(19) United States
(12) Patent Application Publication
(10) Pub. No.: US 2025/0361625 A1
(43) Pub. Date: Nov. 27, 2025

(54) ETCHANT COMPOSITION FOR MOLYBDENUM LAYER AND METHOD FOR FABRICATING INTEGRATED CIRCUIT DEVICE USING THE SAME

(71) Applicant: Samsung Electronics Co., Ltd., Suwon-si, Gyeonggi-do (KR)

(72) Inventors: Minjae SUNG, Suwon-si (KR); Hyeon Jeong KIM, Seongnam-si (KR); Jung-Min OH, Suwon-si (KR); Sabyuk YANG, Suwon-si (KR); Jae Sung LEE, Seongnam-si (KR); Sang Won BAE, Suwon-si (KR)

(73) Assignees: Samsung Electronics Co., Ltd., Suwon-si, Gyeonggi-do (KR); Soulbrain Co., Ltd., Seongnam-si, Gyeonggi-do (KR)

(21) Appl. No.: 18/955,151

(22) Filed: Nov. 21, 2024

(30) Foreign Application Priority Data
Mar. 19, 2024 (KR) 10-2024-0038088

(51) Int. Cl. C23F 1/10; H01L 21/3213; H10B 41/20; H10B 43/20

(52) U.S. Cl. CPC C23F 1/10; H01L 21/32134; H01L 21/32139; H10B 41/20; H10B 43/20

(57) ABSTRACT

An etchant composition may include an oxidizing agent, a chelating agent, a phosphoric acid compound, and an organic solvent. The oxidizing agent may be selected from a nitrate-containing oxidizing agent, a phosphate-containing oxidizing agent, a sulfate-containing oxidizing agent, an acetate-containing oxidizing agent, or a combination thereof. The oxidizing agent may include at least two types of compounds having different oxidizing powers over molybdenum, which may be in a range from 0.1 wt % to 10 wt %, based on a total amount of the etchant composition. The chelating agent may be in a range from 0.001 wt % to 10 wt %, based on the total amount of the etchant composition. The phosphoric acid compound may be in a range from 15 wt % to 25 wt %, based on the total amount of the etchant composition. The organic solvent may correspond to a remaining portion of the etchant composition.

### CROSS-REFERENCE TO RELATED APPLICATIONS

This application claims priority under 35 U.S.C § 119 to Korean Patent Application No. 10-2024-0038088, filed on Mar. 19, 2024 in the Korean Intellectual Property Office, the entire disclosure of which is incorporated by reference herein.

### BACKGROUND

Embodiments of the present disclosure relate to an etchant composition and/or an integrated circuit device using the same, and more particularly, relate to an etchant composition for etching a molybdenum layer and/or a method for fabricating the same.

With the increase in capacity and high integration of integrated circuit devices, a vertical memory device may increase memory capacity by stacking a plurality of memory cells on a substrate in a vertical direction. As the stacking density of the memory cells increases in a vertical memory device, the length of a gate may decrease, and the spacing between adjacent memory cells may decrease in the vertical direction. To enhance the performance of such a vertical memory device, an etching composition may be required to effectively etch a metal thin layer used in the fabricating process of the memory device.

### SUMMARY

Embodiments of the present disclosure provide an etchant composition to control an etch rate of a molybdenum layer used for a highly-integrated circuit device, and to limit and/or minimize residues produced in an etching process.

Embodiments of the present disclosure provide a method for fabricating of an integrated circuit, which includes forming a desired molybdenum pattern while minimizing residues produced in an etching process, by using an etchant composition for a molybdenum layer.

According to an embodiment of the present disclosure, an etchant composition for a molybdenum layer may include an oxidizing agent, a chelating agent, a phosphoric acid compound, and an organic solvent. The oxidizing agent may be selected from a nitrate-containing oxidizing agent, a phosphate-containing oxidizing agent, a sulfate-containing oxidizing agent, an acetate-containing oxidizing agent, or a combination thereof. The oxidizing agent may include at least two types of compounds having different oxidizing powers over molybdenum. The at least two types of compounds may be in a range from 0.1 wt % to 10 wt %, based on a total amount of the etchant composition. The chelating agent may be in a range from 0.001 wt % to 10 wt %, based on the total amount of the etchant composition. The phosphoric acid compound may be in a range from 15 wt % to 25 wt %, based on the total amount of the etchant composition. The organic solvent may correspond to a remaining portion of the etchant composition.

In some embodiments, the oxidizing agent may be the nitrate-containing oxidizing agent and the at least two types of types of compounds may include a first oxidizing agent and a second oxidizing agent. The first oxidizing agent may include metal nitrate, ammonium nitrate, or both metal nitrate and ammonium nitrate, and the second oxidizing agent may include an alkyl ammonium nitrate containing at least one alkyl group having 1 to 6 carbon atoms.

In some embodiments, the first oxidizing agent may be a nitrate of alkali metal, a nitrate of alkaline earth metal, or a nitrate of transition metal.

In some embodiments, the first oxidizing agent may be at least one of lithium nitrate (LiNO₃), sodium nitrate (NaNO₃), potassium nitrate (KNO₃), aluminum nitrate (Al(NO₃)₃), magnesium nitrate (Mg(NO₃)₂), copper nitrate (Cu(NO₃)₂), ammonium nitrate (NH₄NO₃), cobalt nitrate (Co(NO₃)₂), nickel nitrate (Ni(NO₃)₂), zinc nitrate (Zn(NO₃)₂), tungsten nitrate (W(NO₃)₂), or a combination thereof.

In some embodiments, the second oxidizing agent may be tetraalkyl ammonium nitrate.

In some embodiments, the second oxidizing agent may be at least one of tetramethylammonium nitrate ((CH₃)₄N(NO₃)), tetraethylammonium nitrate ((C₂H₅)₄N(NO₃)), tetrapropylammonium nitrate ((C₃H₇)₄N(NO₃)), tetrabutylammonium nitrate (((C₄H₉)₄)NNO₃), tetrapentylammonium nitrate ((C₅H₁₁)₄N(NO₃)), tetrahexylammonium nitrate ((C₆H₁₃)₄N(NO₃)), or a combination thereof.

In some embodiments, the oxidizing agent may include one of ammonium phosphate ((NH₄)₃PO₄), ammonium sulfate ((NH₄)₂SO₄), ammonium acetate (C₂H₇NO₂), or a combination thereof.

In some embodiments, the chelating agent may be a multidentate ligand with at least two bonding sites.

In some embodiments, the chelating agent may be at least one of alkyl diamine having 2 to 14 carbon atoms, alkyl triamine having 3 to 14 carbon atoms, or a combination thereof.

In some embodiments, the chelating agent may be at least one of ethylenediaminetetraacetic acid (EDTA; C₁₀H₁₆N₂O₈), nitrilotriacetic acid (C₆H₉NO₆), trans-_{1,2}-diaminocyclohexane-N,N,N′,N′-tetraacetic acid (C₁₄H₂₂N₂O₈), diethylenetriaminepentaacetic acid (C_{14,}H₂₃N₃O₁₀), ethylene glycol-O,O′-Bis(2-aminoethyl) N,N,N′,N′-tetraacetic acid (C₁₄H₂₄N₂O₁₀), triethylenetetramine-N,N,N′,N,N″′,N″′-hexaacetic acid; C₁₈H₃₀N₄O₁₂), N,N-Bis(2-hydroxyethyl) glycine (C₆H₁₃NO₄), iminoacetic acid (C₄H₇NO₄), nitrilotrimethylphosphonic acid (N(CH₂PO₃H₂)₃), or a combination thereof.

In some embodiments, the phosphoric acid compound may be at least one of phosphoric acid, phosphate, phosphonic acid, phosphonic acid salt, or a combination thereof.

In some embodiments, the organic solvent may include a non-aqueous organic solvent selected from a carboxylic acid having 1 to 7 carbon atoms, a carboxylic acid compound having 1 to 7 carbon atoms, an alcohol compound having 1 to 7 carbon atoms, a carbonic ester compound having 1 to 7 carbon atoms, and a combination thereof.

In some embodiments, the organic solvent may include at least one of formic acid (CH₂O₂), acetic acid (C₂H₄O₂), acrylic acid (C₃H₄O₂), propionic acid (C₃H₆O₂), butyric acid (C₄H₈O₂), valeric acid (C₅H₁₀O₂), hexanoic acid (C₆H₁₂O₂), heptanoic acid (C₇H₁₄O₂), lactic acid (C₃H₆O₃), propylene carbonate (C₄H₆O₃), dimethyl carbonate (C₃H₆O₃), or a combination thereof.

In some embodiments, the organic solvent may be 75 wt % to 85 wt % of the etchant composition, based on the total amount of the etchant composition.

An embodiment of the present disclosure may include a method for patterning a molybdenum layer may use the etchant composition for etching the molybdenum layer, and the method may include forming the molybdenum layer on a substrate, forming an etch stop layer on the molybdenum layer, and etching the molybdenum layer using the etchant composition and employing the etch stop layer as a mask.

According to an embodiment of the present disclosure, a method for forming a molybdenum pattern may include forming a support structure on a substrate, the support structure extending in a horizontal direction and defining a plurality of spaces spaced apart from each other in a vertical direction; forming a molybdenum layer by filling molybdenum in the plurality of spaces; and removing a portion of the molybdenum layer in a vertical direction perpendicular to a top surface of the substrate using an etchant composition for the molybdenum layer, such that molybdenum patterns filling the plurality of spaces are formed, the molybdenum patterns being spaced apart from each other in the vertical direction. The etchant composition for the molybdenum layer may include an oxidizing agent, a chelating agent, a phosphoric acid compound, and an organic solvent. The oxidizing agent may be selected from a nitrate-containing oxidizing agent, a phosphate-containing oxidizing agent, a sulfate-containing oxidizing agent, an acetate-containing oxidizing agent, or a combination thereof. The oxidizing agent may include at least two types of compounds having different oxidizing powers over molybdenum. The at least two types of compounds may be in a range from 0.1 wt % to 10 wt %, based on a total amount of the etchant composition. The chelating agent may be in a range from 0.001 wt % to 10 wt %, based on the total amount of the etchant composition. The phosphoric acid compound may be in a range from 15 wt % to 25 wt %, based on the total amount of the etchant composition. The organic solvent may correspond to a remaining portion of the etchant composition.

According an embodiment of the present disclosure, a method for fabricating a integrated circuit device is provided. The integrated circuit device may include a plurality of word lines, a plurality of bit lines, and channel structures connected to the word lines and the bit lines. The method may include forming a stack structure by alternately stacking a plurality of first layers and a plurality of second layers on a substrate; forming a channel hole through the stack structure in a vertical direction; forming the channel structure in the channel hole; forming a word line cut region through the stack structure in the vertical direction, the word line cut region extending in a first direction parallel to a top surface of the substrate, the word line cut region exposing the plurality of first layers; forming a plurality of word line spaces by removing the plurality of first layers; forming a molybdenum layer by filling the plurality of word line spaces, the molybdenum layer covering a surface of plurality of second layers exposed through the word line cut region; removing a portion of the molybdenum layer using an etchant composition, thereby forming a plurality of word lines including a plurality of molybdenum patterns, the plurality of word line filling the plurality of word line spaces and being spaced apart from each other in the vertical direction; and forming bit lines on the stack structure. The etchant composition for the molybdenum layer may include an oxidizing agent, a chelating agent, a phosphoric acid compound, and an organic solvent. The oxidizing agent may be selected from a nitrate-containing oxidizing agent, a phosphate-containing oxidizing agent, a sulfate-containing oxidizing agent, an acetate-containing oxidizing agent, or a combination thereof. The oxidizing agent may include at least two types of compounds having different oxidizing powers over molybdenum. The at least two types of compounds may be in a range from 0.1 wt % to 10 wt %, based on a total amount of the etchant composition. The chelating agent may be in a range from 0.001 wt % to 10 wt %, based on the total amount of the etchant composition. The phosphoric acid compound may be in a range from 15 wt % to 25 wt %, based on the total amount of the etchant composition. The organic solvent may correspond to a remaining portion of the etchant composition.

### BRIEF DESCRIPTION OF THE FIGURES

The above and other objects and features of the present disclosure will become apparent by describing in detail embodiments thereof with reference to the accompanying drawings.

FIG. 1 is a flowchart illustrating a method for patterning a molybdenum layer according to an embodiment of the present disclosure.

FIGS. 2A to 2D are cross-sectional views sequentially illustrating the method for patterning a molybdenum layer of FIG. 1.

FIG. 3 is a flowchart illustrating a method for forming the molybdenum pattern according to an embodiment of the present disclosure.

FIGS. 4A to 4C are cross-sectional views sequentially illustrating the method for forming the molybdenum pattern of FIG. 3.

FIGS. 5A to 5D are views illustrating the integrated circuit device realized through the method for fabricating the integrated circuit device according to an embodiment of the present disclosure and illustrates a VNAND memory device in detail.

FIGS. 6A to 6J are cross-sectional views illustrating a region corresponding to ‘P3’ of FIG. 5C according to a process sequence to describe the method for fabricating the integrated circuit device according to embodiments of the present disclosure.

FIGS. 7A to 7C are photographs obtained by capturing a word line cut region after partially etching a molybdenum layer.

FIG. 8 is an etching result for the molybdenum layer using etchant compositions including oxidizing agents including an organic acid salt/an inorganic acid salt.

FIGS. 9A to FIG. 9D are photographs obtained by capturing etching results of etchant compositions according to the related art and an etchant composition according to the present disclosure, when a plurality of word lines are formed by removing a portion of a molybdenum layer using an etchant composition, in a method for fabricating the integrated circuit device.

### DETAILED DESCRIPTION

Hereinafter, some example embodiments of the present disclosure will be described in more detail to describe the present disclosure in more detail. However, the present disclosure is not limited to the following description and may be embodied in other forms.

Unless specified otherwise, all numbers for expressing an amount, or a reaction condition of a component in the present disclosure and claims should be interpreted as having the meaning of “about” in all cases. Accordingly, unless specified conversely, a numeric parameter described in the present disclosure and claims have an approximate value varying depending on the desired characteristics to be obtained based on the subject matters of the present disclosure. As described in the present disclosure, the term “about” is intended to include variations of ±20% in some embodiments, ±10% in some embodiments, ±5% in some embodiments, ±1% in some embodiments, ±0.5% in some embodiments, and ±0.1% in some embodiments, when the value or the amount of mass, weight, time, volume, concentration, or percentage is described, and the variations are included, when the variations is appropriate to perform a method disclosed.

In addition, units used without any special mention in this specification are based on weight, for example, “%” or “unit of ratio” refers to “weight %” or “weight ratio”, and “weight %” refers to “weight %” in which any one component occupies in a composition based on the whole amount of the composition.

In addition, the numerical range used herein includes a lower limit value, an upper limit value, all values in the range from the lower limit value to the upper limit value, increments logically derived the form and width of the defined range, all double-limited values, and all possible combinations between an upper limit value and a lower limit value in the numerical range defined in mutually different forms. Values outside the numerical range which are likely to occur due to experimental errors or rounding of values are also included in the defined numerical range unless otherwise defined in the specification of the present disclosure.

The term “include” in the present disclosure, which has a meaning the same as the term “comprise”, “contain”, “have”, or “characterized”, may be open-type (comprise) description, and does not exclude an element, a material, or a process which is not additionally described. However, the description “include” may be any one of a closed-type description (consist of) or a partially closed-type description (consist essentially of) depending on occasions.

Hereinafter, an example embodiment of the present disclosure will be described with reference to accompanying drawings in more detail.

The present disclosure relates to a non-aqueous composition serving as a composition for etching a molybdenum layer. The composition may be used to remove a portion of the molybdenum layer to make a pattern.

The molybdenum layer is provided in the process of forming electrodes, wirings, and other conductive patterns used in an electronic device, and is a target to be patterned by using the etchant composition according to an embodiment of the present disclosure. In this case, the electronic device, which is provided in various forms, may be, for example, a semiconductor substrate, an integrated circuit, a memory device, or a display device. Especially, the electronic device may be the memory device. Among memory devices, the electronic device may be a VNAND device. However, according to an embodiment of the present disclosure, the type of the electronic device is not limited thereto.

According to an embodiment of the present disclosure, the molybdenum layer, which is a layer including a molybdenum ingredient, may be a layer including only molybdenum or a layer (hereinafter, a molybdenum alloy layer) including the alloy of molybdenum. The molybdenum alloy layer may be a layer consisting essentially of molybdenum. For example, the molybdenum alloy layer may be a layer including more than 50 wt % of molybdenum among materials for forming the layer, on a weight basis. The molybdenum alloy layer may include the alloy of the molybdenum and various types of metal. For example, the molybdenum alloy layer may include the alloy of molybdenum and the combination of at least one selected from the group consisting of tungsten, titanium, tantalum, chromium, neodymium, nickel, indium, and tin. For example, the molybdenum alloy layer may include molybdenum-tungsten (Mo—W), molybdenum-titanium (Mo—Ti), molybdenum-niobium (Mo—Nb), molybdenum-chromium (Mo—Cr), or molybdenum-tantalum (Mo—Ta). Molybdenum may have an ion oxidation state of −3, −1, +1, +2, +3, +4, +5, or +6, and the formula for the molybdenum alloy may vary depending on the ion oxidation state. According to an embodiment of the present disclosure, the molybdenum layer may also include a nitride layer of molybdenum or an oxide layer of molybdenum.

According to an embodiment of the present disclosure, the etchant composition is used to etch a single molybdenum layer, and is not excluded in etching a molybdenum layer in a multi-layer structure including the molybdenum layer and a different metal layer.

An etching composition according to an embodiment of the present disclosure includes an oxidizing agent, a chelating agent, a phosphoric acid compound, and a residual amount of an organic solvent.

The oxidizing agent may include at least two oxidizing agents having mutually different oxidizing rates when oxidizing the molybdenum layer.

At least two oxidizing agents mutually different from each other may include two types of oxidizing agents selected from among oxidizing agents, which show the difference in the oxidizing power over molybdenum, in various oxidizing agents. According to an embodiment of the present disclosure, when the at least two oxidizing agents mutually different from each other are a first oxidizing agent and a second oxidizing agent, any one of the first oxidizing agent and the second oxidizing agent may have the oxidizing power corresponding to at least 40%, at least 70%, or at least 90% of the oxidizing power of a remaining oxidizing agent of the first and second oxidizing agents. The difference in oxidizing power between oxidizing agents exerts an influence the oxidizing rate of the molybdenum layer to make the difference in etch rate. According to an embodiment of the present disclosure, based on the difference in etch rate when the first oxidizing agent and the second oxidizing agent, any one of the first oxidizing agent and the second oxidizing agent may have the etch rate corresponding to at most 50%, or at most 70% of the remaining agent of the first oxidizing agent and the second oxidizing agent. In addition, the diameter of a cation contained in the any one of the first oxidizing agent and the second oxidizing agent may be at least 10%, at least 100%, at least 150%, or at least 200% of the diameter of a cation contained in the remaining oxidizing agent of the first oxidizing agent and the second oxidizing agent.

The oxidation power may vary depending on various factors such as the degree of dissociation of the cation contained in the oxidizing agent, the density of electrons in the cation, or the size of the cation. The oxidation power may be determined based on at least one of factors, such as the degree of dissociation of the cation contained in the oxidizing agent, the density of electrons in the cation or the size of the cation. According to an embodiment of the present disclosure, the oxidizing agent may be selected as an oxidizing agent containing cations having various sizes. In other words, according to an embodiment of the present disclosure, the oxidizing agent may include the first oxidizing agent and the second oxidizing agent containing cations having mutually different sizes. In this case, the size of the cation may be determined, based on the quantity of charges per unit mass of the cation.

According to an embodiment of the present disclosure, the first oxidizing agent may contain, as a cation, an inorganic acid salt and/or an organic acid salt of metal having a smaller size, or may contain, as the cation, an inorganic acid salt and/or an organic acid salt containing a smaller ion, such as an ammonium ion. The inorganic acid salt and/or the organic acid salt may be selected from among inorganic acid salts, such as nitrate, phosphate, sulfate, chlorite, iodate, or perborate, and/or an organic acid salt such as acetate.

Metal contained in a metal inorganic acid salt/organic acid salt, which may be used as the first oxidizing agent, may be alkali metal, alkaline earth metal, and/or transition metal. For example, the first oxidizing agent may be an inorganic acid salt and/or an organic acid salt such as lithium, potassium, aluminum, magnesium, and copper.

According to an embodiment of the present disclosure, the first oxidizing agent may be selected from among lithium nitrate (LiNO₃), sodium nitrate (NaNO₃), potassium nitrate (KNO₃), aluminum nitrate (Al(NO₃)₃), magnesium nitrate (Mg(NO₃)₂), copper nitrate (Cu(NO₃)₂), ammonium nitrate (NH₄NO₃), cobalt nitrate (Co(NO₃)₂), nickel nitrate (Ni(NO₃)₂), zinc nitrate (Zn(NO₃)₂), tungsten nitrate (W(NO₃)₂), ammonium phosphate ((NH₄)₃PO₄), ammonium sulfate ((NH₄)₂SO₄), ammonium chlorite (NH₄ClO₂), ammonium chlorate (NH₄C₁₀₃), ammonium perchlorate (NH₄ClO₄), ammonium hypochlorite (NH₄ClO), ammonium iodate (NH₄IO₃), ammonium periodate (NH₄IO₄), ammonium perborate (NH₄BO₃), ammonium bisulfate (NH₄)HSO₄), or the combination thereof.

The second oxidizing agent may be an inorganic acid salt and/or an organic acid salt containing a cation larger than the cation the first oxidizing agent. The inorganic acid salt and/or the organic acid salt may be selected from among inorganic acid salts, such as nitrate, phosphate, sulfate, chlorite, iodate, or perborate, and/or an organic acid salt such as acetate.

The cation of the second oxidizing agent is an ammonium ion, in which hydrogen may be substituted with at least one alkyl group having 1 to 6 carbon atoms. For example, the cation of the second oxidizing agent may be substituted with at least one of four hydrogens of ammonium ions, and with up to four hydrogens of ammonium ions.

According to an embodiment of the present disclosure, an alkyl group having 1 to 6carbon atoms is an aliphatic hydrocarbon group. The alkyl group may be a saturated alkyl group which does not contain any double or triple bonds. Alternatively, the alkyl group may be an unsaturated alkyl group containing at least one double bond or triple bond. The alkyl group may be branched, linear, or cyclic, regardless of the saturation state of the alkyl group.

According to an embodiment of the present disclosure, the cation of the second oxidizing agent may be a tetraalkyl ammonium ion obtained by substituting all four hydrogens of ammonium ions with the alkyl group having 1 to 6 carbon atoms.

According to an embodiment of the present disclosure, the second oxidizing agent may be selected from among tetramethylammonium nitrate ((CH₃)₄N(NO₃)), tetraethylammonium nitrate ((C₂H₅)₄N(NO₃)), tetrapropylammonium nitrate ((C₃H₇) ₄N(NO₃)), tetrabutylammonium nitrate (((C₄H₉)₄)NNO₃), tetrapentylammonium nitrate ((C₅H₁₁)₄N(NO₃)), tetrahexylammonium nitrate ((C₆H₁₃)₄N(NO₃)), tetramethylammonium chlorite ((N(CH₃)₄)ClO₂), tetramethylammonium chlorate ((N(CH₃) ₄)ClO₃), tetramethylammonium iodate ((N(CH₃)₄)IO₃), tetramethylammonium perborate ((N(CH₃)₄)BO₃), tetramethylammonium perchlorate ((N(CH₃)₄)ClO₄), tetramethylammonium periodate ((N(CH₃)₄)IO₄), tetramethylammonium persulfate((N(CH₃)₄)S₂O₈), tetrabutylammonium peroxymonosulfate, or the combination thereof. In addition, the second oxidizing agent may have a trialkyl group or a dialkyl group, instead of the tetraalkyl group, which is described above, in the caution of the above-described compound.

According to an embodiment of the present disclosure, the first oxidizing agent and the second oxidizing agent may be selected from among nitrates. In other words, the first oxidizing agent and the second oxidizing agent may include a first oxidizing agent selected from a metal nitrate, ammonium nitrate, or the combination thereof, and a second oxidizing agent selected from alkyl ammonium nitrate including containing at least one alkyl group having 1 to 6 carbon atoms. For example, the first oxidizing agent may be selected from among lithium nitrate (LiNO₃), sodium nitrate (NaNO₃), potassium nitrate (KNO₃), aluminum nitrate (Al(NO₃)₃), magnesium nitrate (Mg(NO₃)₂), copper nitrate (Cu(NO₃)₂), ammonium nitrate (NH₄NO₃), cobalt nitrate (Co(NO₃)₂), nickel nitrate (Ni(NO₃)₂), zinc nitrate (Zn(NO₃)₂), tungsten nitrate (W(NO₃)₂), or the combination thereof. The second oxidizing agent may be selected from among tetramethylammonium nitrate ((CH₃)₄N(NO₃)), tetraethylammonium nitrate ((C₂H₅)₄N(NO₃)), tetrapropylammonium nitrate ((C₃H₇)₄N(NO₃)), tetrabutylammonium nitrate (((C₄H₉)₄)NNO₃), tetrapentylammonium nitrate ((C₅H₁₁)₄N(NO₃)), tetrahexylammonium nitrate ((C₆H₁₃)₄N(NO₃)), or the combination thereof.

The oxidizing agent may oxidize molybdenum atoms in the molybdenum layer, and may be provided in the range from 0.01 wt % to 20 wt %, based on 100wt %, which is a total amount of the etchant composition. For example, the oxidizing agent may be provided in the range from 0.0.5 wt % to 15 wt %, or may be provided in the range from 0.1 wt % to 10 wt %. When the oxidizing agent is used in less than 0.01 wt %, the molybdenum layer may not be sufficiently oxidized. When the oxidizing agent is used in more than 20 wt %, the molybdenum layer may be excessively oxidized.

The second oxidizing agent may include at least one type of material selected from among ammonium acetate (C₂H₇NO₂), ammonium phosphate ((NH₄)₃PO₄), ammonium sulfate ((NH₄)₂SO₄), aluminum nitrate (Al(NO₃)₃), tetramethylammonium nitrate ((CH₃)₄N(NO₃)), tetraethylammonium nitrate ((C₂H₅)₄N(NO₃)), tetrapropylammonium nitrate ((C₃H₇)₄N(NO₃)), tetrabutylammonium nitrate (((C₄H₉)₄)NNO₃), tetrapentylamonium nitrate ((C₅H₁₁)₄N(NO₃)), tetrahexylamonium nitrate ((C₆H₁₃)₄N(NO₃)), or the combination thereof.

According to an embodiment of the present disclosure, the etch rate may be controlled based on the ratio between the contents of the first oxidizing agent and the second oxidizing agent. Since the first oxidizing agent and the second oxidizing agent have different oxidizing power over molybdenum, the content of an oxidizing agent having greater oxidizing power may be increased to increase the etch rate. To reduce the etch rate, the content of the oxidizing agent having the greater oxidizing power may be reduced. According to an embodiment of the present disclosure, The proportion of the first oxidizing agent and the proportion of the second oxidizing agent, which are appropriate to form a pattern in a specific shape, may be variously set depending on the thickness of the molybdenum layer, the purity of the molybdenum, the contact area with the molybdenum layer, the temperature of the etchant, and the flow rate of the etchant.

According to an embodiment of the present disclosure, to form the specific shape (e.g., a recess to be described later), the first oxidizing agent may be provided in the range from 0.001 wt % to 2.0 wt %, based on 100 wt %, which is a total amount of the etchant composition. In addition, the first oxidizing agent may be provided in the range from 0.0.5 wt % to 1.5 wt %. Alternatively, the first oxidizing agent may be provided in the range from 0.1 wt % to 1.0 wt %. Alternatively, the first oxidizing agent may be provided in the range from 0.1 wt % to 0.6 wt %. When the first oxidizing agent deviates from the range, the variation of the degree of etching may be deteriorated such that the oxidization is irregularly oxidized. When the first oxidizing agent is used in less than 0.001 wt %, the molybdenum layer may not be sufficiently oxidized. When the first oxidizing agent is used in more than 2.0 wt %, the molybdenum layer may be excessively and irregularly oxidized. Especially, when an amount of the first oxidizing agent exceeds the above range, the dispersion of the degree of etching is deteriorated.

The second oxidizing agent may be provided in the range from 0.001 wt % to 4.0 wt %, based on 100 wt %, which is a total amount of the etchant composition. For example, the second oxidizing agent may be provided in the range from 0.005 wt % to 3 wt %. Alternatively, the second oxidizing agent may be provided in the range from 0.01 wt % to 2 wt %. When the second oxidizing agent is used in less than 0.001 wt %, the molybdenum layer may not be sufficiently oxidized. When the second oxidizing agent is used in more than 4.0 wt %, the molybdenum layer may be excessively oxidized.

According to an embodiment of the present disclosure, the ratio of the first oxidizing agent to the second oxidizing agent may be about (0.8 to 1.3):2, or about 1:2. In addition, the first oxidizing agent and the second oxidizing agent may be contained at the ratio of 0.8:1 to 1.3:1 in the oxidizing agent.

According to an embodiment of the present disclosure, the chelating agent may contain an amine-based compound or a non-amine-based compound

The amine-based compound may include aminoethyl ethanolamine, N-methylaminoethanol, aminoethoxyethanol, dimethylaminoethoxyethanol, diethanolamine, N-methyldiethanolamine, monoethanolamine (MEA), triethanolamine (TEA), 1-amino-2-propanol, 2-amino-1-butanol, isobutanolamine, triethylenediamine, 4-(2-hydroxyethyl) morpholine (HEM), m-xylene diamine (MXDA), or the combination thereof.

The non-amine compounds include ethylene diamine tetraacetic acid (EDTA), iminodiaacetic acid (IDA), 2-(hydroxyethyl) iminodiaacetic acid (HIDA), nitrilotriacetic acid, thiourea, 1,1,3,3-tetramethylurea, urea, urea derivative, uric acid, alanine, arginine, asparagine, aspartic acid, cysteine, glutamic acid, glutamine, histidine, isoleucine, leucine, lysine, methionine, phenylalanine, proline, serine, threonine, tryptophan, tyrosine, valine, 1,5,9-triazacyclodecane-N,N′,N″-tris (methylene phosphonic acid; DOTRP), 1,4,7,10-tetraaxyclodecane-N,N′,N″,N″′-tetrakis (methylene phosphonic acid; DOTP), nitrilotris (methylene) triphosphonic acid, diethylenediamine pentakis (methylene phosphonic acid;

DETAP), bis (hexamethylene) triamine pentamethylene phosphonic acid, 1,4,7-triazacyclononan-N,N′,N′″-tris (methylene phosphonic acid; NOTP), hydroxyethyl diphosphonate, nitrileotris (methylene) phosphonic acid, 2-phosphono-butane-1,2,3,4-tetracarboxylic acid, carboxyethyl phosphonic acid, aminoethyl phosphonic acid, glyphosate, ethylene diamine tetra (methylene phosphonic acid) phenylphosphonic acid, oxalic acid, succinic acid, maleic acid, malic acid, malonic acid, adipic acid, phthalic acid, lactic acid, citric acid, sodium citrate, potassium citrate, ammonium citrate, tricarvalic acid, trimethylolpropionic acid, tartaric acid, glucuronic acid, 2-carboxypyridine, 4,5-dihydroxy-1,3-benzendisulfonic acid disodium salt, methylphosphonic acid, phenylphosphonic acid, aminotris (methylphosphonic acid), 1-hydroxyetene-1,1-diphosphonic acid, or the combination thereof. In addition, the non-amine compound may employ an azole-based compound, and the azole-based compound may be imidazole, pyrazole, triazole, tetrazole, pentazole, oxazole, isoxazole, oxdiazole, furazan, thiazole, isothiazole, or thiadiazole.

According to an embodiment of the present disclosure, the chelating agent may be provided in the form of a multidentate ligand to improve the binding rate when chemically bonded or physically bonded to molybdenum atoms and/or ions. In other words, the chelating agent according to an embodiment of the present disclosure may be a ligand having at least two coordinate bonding sites. In this case, the chelating agent may be selected from among alkyl diamine having 2 to 14 carbon atoms, alkyl triamine having 3 to 14 carbon atoms, or the combination thereof. For example, the chelating agent may be selected from among ethylenediaminetetraacetic acid (EDTA; C₁₀H₁₆N₂O₈), nitrilotriacetic acid (C₆H₉NO₆), trans-1-2 diaminocyclohexane-N,N,N′,N′-tetraacetic acid (C₁₄H₂₂N₂O₈), diethylenetriaminepentaacetic acid (C₁₄H₂₃N₃O₁₀), ethylene glycol-O,O′-Bis(₂-aminoethyl) N,N,N′,N′-tetraacetic acid (C₁₄H₂₄N₂O₁₀), triethylenetetramine-N,N,N′,N,N″′,N′″-hexaacetic acid (C₁₈H₃₀N₄O₁₂), N,N-Bis(₂-hydroxyethyl) glycine (C₆H₁₃NO₄), iminoacetic acid (C₄H₇NO₄), nitrilotrimethylphosphonic acid (N(CH₂PO₃H₂)₃), or the combination thereof.

According to an embodiment of the present disclosure, the chelating agent may be provided in the range from 0.0001 wt % to 20 wt %, based on 100 wt % which is the total amount of the etchant composition. For example, the chelating agent may be provided in the range from 0.000.5 wt % to 15 wt %, or may be provided in the range from 0.001 wt % to 10 wt %. When the chelating agent is contained in an amount less than the range, the molybdenum layer may not be sufficiently dissolved by the chelating agent. When the chelating agent is contained in an amount more than the range, the etch rate may be excessive reduced.

Phosphoric acid compound may be used mainly for etching of the molybdenum layer.

In the etchant composition according to an embodiment of the present disclosure, the phosphoric acid compound may include phosphoric acid, phosphate, phosphonic acid, a salt of phosphonic acid, or the combination thereto. According to an embodiment of the present disclosure, the phosphoric acid may include anhydrous phosphoric acid, polyphosphate, or the combination thereof.

According to an embodiment of the present disclosure, the phosphoric acid compound may be selected from among phosphoric acid (H₃PO₄), pyrophosphoric acid (H₄P₂O₇), tripolyphosphoric acid (H₅P₃O₁₀), tetrapolyphosphoric acid (H₆P₄O₁₃), trimethyl phosphate ((CH₃O)₃PO), triethyl phosphate ((C₂H₅)₃PO₄), tributyl phosphate (CH₃(CH₂)₃O)₃PO), triphenyl phosphate ((C₆H₅O)₃PO), triallyl phosphate (C₉H₁₅O₄P), tris (trimethylsilyl) phosphate (C₉H₂₇O₄PSi₃), phosphoric anhydride (P₄O₁₀), phenylphosphonic acid ((C₆H₅P(O)(OH)₂)), diphenylphosphinic acid ((C₆H₅)₂P(O)OH), methylphosphonic acid ((CH₃P(O)(OH)₂), dimethylphophinic acid ((CH₃)₂P(O)OH), calcium phosphate ((Ca₃(PO₄)₂), monopotassium phosphate (KH₂PO₄), dipotassium phosphate (K₂HPO₄), tripotassium phosphate (K₃PO₄), monosodium phosphate (NaH₂PO₄), disodium phosphate (Na₂HPO₄), trisodium phosphate (Na₃PO₄), amino phosphate (H₂NO₄P), ammonium phosphate ((NH₄)₃PO₄), barium phosphate (Ba₃(PO₄)₂), bis(2-ethylhexyl) hydrogen phosphate (C₁₆H₃₅O₄P), boron phosphate (BPO₄), cesium hexafluorophosphate (CsF₆P), dodecyl phosphate (C₁₂H₂₇O₄P), ethylene chlorophosphate (C₂H₄ClO₃P), sodium Hexafluorophosphate (F₆NaP), benzotriazol-1-yloxy)tris(dimethylamino)phosphonium hexafluorophosphate (C₁₂H₂₂F₆N₆OP₂), N-triflyl phosphoramides (CH₅F₃N₃O₃PS), or the combination thereof.

The phosphoric acid compound may substantially etch the molybdenum layer oxidized by the oxidizing agent, and may be provided in the range from 5 wt % to 40 wt % based on 100 wt % which is the total amount of the etchant composition. For example, the phosphoric acid may be provided in the range from 10 wt % to 30 wt %, or may be provided in the range from 15 wt % to 25 wt %. When the phosphoric acid compound is contained in an amount less than the range, the molybdenum layer may be insufficiently etched by the phosphoric acid compound. Accordingly, the molybdenum pattern may not be formed. When the phosphoric acid compound is contained in an amount more than the range, the molybdenum layer is excessive etched, so a desired molybdenum pattern may not be formed.

An organic solvent may be a non-aqueous organic solvent selected from carboxylic acid

having 1 to 12 carbon atoms, a carboxylic acid compound having 1 to 12 carbon atoms, an alcohol compound having 1 to 12 carbon atoms, a carbonic ester compound having 1 to 12 carbon atoms, or the combination thereof.

According to an embodiment of the present disclosure, the organic solvent may be selected from among formic acid (CH₂O₂), acetic acid, acrylic acid (C₃H₄O₂), propionic acid (C₃H₆O₂), butyric acid (C₄H₈O₂), valeric acid (C₅H₁₀O₂), hexanoic acid (C₆H₁₂O₂), heptanoic acid (C₇H₁₄O₂), lactic acid (C₃H₆O₃), propylene carbonate (C₄H₆O₃), dimethyl carbonate (C₃H₆O₃), methyl acetate, ethyl acetate, propyl acetate, isopropyl acetate, ethanol, methanol, butanol, propanol, isopropanol, pentanol, hexanol, 2-ethyl-1-hexanol, heptanol, octanol, ethylene glycol, propylene glycol, butylene glycol, ethylene carbonate, diethyl carbonate, ethyl methyl carbonate, propylene carbonate, methylpropyl carbonate, butylene carbonate, dipropylene glycol, diethylene glycol monomethyl ether, triethylene glycol monomethyl ether, diethylene glycol monomethyl ether, triethylene glycol monopropyl ether, ethylene glycol monopropyl ether, ethylene glycol monobutyl ether, diethylene glycol monobutyl ether, triethylene glycol monobutyl ether, ethylene glycol monohexyl ether, diethylene glycol monohexyl ether, ethylene glycol phenyl ether, propylene glycol methyl ether, dipropylene glycol methyl ether (DPGME), tripropylene glycol methyl ether (TPGME), dipropylene glycol dimethyl ether, dipropylene glycol diethyl ether, propylene glycol n-propyl ether, dipropylene glycol n-propyl ether (DPGPE), tripropylene glycol n-propyl ether, propylene glycol n-butyl ether, dipropylene glycol n-butyl ether, tripropylene glycol n-butyl ether, propylene glycol phenyl ether, 2,3-dihydrodecafluoropentane, ethyl perfluorobutyl ether, methyl perfluorobutyl ether, alkyl group carbonate, alkylene carbonate, 4-methyl-2-pentanol, diethylene glycol isopropyl methyl ether, but the present disclosure is not limited thereto.

According to an embodiment of the present disclosure, the organic solvent may be a non-aqueous organic solvent selected from among carboxylic acid having 1 to 7 carbon atoms, a carboxylic acid compound having 1 to 7 carbon atoms, an alcohol compound having 1 to 12 carbon atoms, a carbonic ester compound having 1 to 7 carbon atoms, or the combination thereof. For example, the organic solvent may be selected from among formic acid (CH₂O₂), acetic acid (C₂H₄O₂), acrylic acid (C₃H₄O₂), propionic acid (C₃H₆O₂), butyric acid (C₄H₈O₂), valeric acid (C₅H₁₀O₂), hexanoic acid (C₆H₁₂O₂), heptanoic acid (C₇H₁₄O₂), lactic acid (C₃H₆O₃), propylene carbonate (C₄H₆O₃), dimethyl carbonate (C₃H₆O₃), or the combination thereof.

The organic solvent may contain a remaining content of 100 wt % except for the oxidizing agent, the chelating agent or the phosphoric compound. For example, the etchant composition may be provided in the range from 50 wt % to 95 wt %, based on 100 wt % which is the total amount of the etching component. For example, the etchant composition may be provided in the range from 60 wt % to 90 wt %, or the range from 75 wt % to 85 wt %.

According to an embodiment of the present disclosure, the etchant composition may not contain water. In other words, water is not contained in the etchant composition substantially. Even if water is contained in the etchant composition, water is not contained at the level of impurities. Accordingly, for example, water may be contained in less than 5 wt %, less than 2 wt %, less than 1 wt %, or less than 0.1 wt %, based on 100 wt % which is the total amount of the etchant composition. In other words, inorganic acid, an oxidizing agent, and an etching suppressor contained in the etchant composition are prepared in the form of an anhydrous material. When at least one of the inorganic acid, the oxidizing agent, and the etching suppressor includes a material having a purity of less than 100%, a smaller amount of water may be contained in the material, but water as an essential component of the composition is not contained. In addition, according to an embodiment of the present disclosure, the etchant composition according to the embodiments of the present disclosure may not include hydrogen peroxide (H₂O₂).

The etchant composition according to an embodiment of the present disclosure is to etch the molybdenum layer at an etch rate controlled, and may limit and/or prevent residues produced in the process of etching the molybdenum layer. Molybdenum is a metal which is relatively vulnerable to oxidation. Accordingly, when removing the molybdenum layer through a conventional etchant composition, the etch rate may be too fast to control the etching amount of the molybdenum layer. In addition, undesirable residues are produced when the molybdenum layer is etched, and the fabricating process of the integrated circuit device may be complicate.

In the etchant composition according to embodiments of the present disclosure, since the oxidizing agent is provided in the form of a salt, rather than the form of hydrogen ions (H+), the molybdenum layer is limited and/or prevented from being directly corroded due to H+. Especially, the etch rate of molybdenum may be sensitively changed depending on the amount of the oxidizing agent. In particular, the molybdenum layer may be directly etched by hydrogen ions contained in the strong acid composition. Accordingly, when hydrogen ions are present, the molybdenum layer may be irregularly etched due to the difference in flow rate due to the flowing of the etchant composition, and may be locally discolored due to the irregular etching. However, according to an embodiment of the present disclosure, since an organic acid salt/inorganic salt is used as the oxidizing agent, such a defect does not be caused.

According to an embodiment of the present disclosure, the oxidizing agent may oxidize molybdenum atoms contained in the molybdenum layer, which is a target to be etched, and the oxidized molybdenum oxide may be dissolved by a phosphoric acid compound. For example, when nitrate is used as the oxidizing agent, molybdenum atoms contained in the molybdenum layer may be oxidized to obtain molybdenum oxide (e.g., a molybdenum oxide (MoO₃)). Next, when anhydrous phosphoric acid is used as a substantial etchant component, the molybdenum oxide may be dissolved by the anhydrous phosphoric acid. In this case, the dissolution reaction may proceed to the following reaction equation or a similar reaction equation

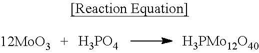

Regarding the etchant composition according to an embodiment of the present disclosure, oxidizing agents different from each other in size of cation are used to oxidize the molybdenum layer, such that the reactivity with the molybdenum layer is differently appeared. Accordingly, the oxidizing degree of the molybdenum layer and the rate of oxidizing the molybdenum layer by the oxidizing agent may be easily controlled.

When the oxidizing agents are different from each other in size of cation, the two oxidizing agents show different degrees of ionization dissociation, and show the difference in reaction surficial area with the molybdenum layer due to the difference in size of cation. The oxidizing agent according to an embodiment of the present disclosure includes at least one type of first oxidizing agent and at least one type of second oxidizing agent, thereby efficiently controlling the oxidization of the molybdenum layer.

In addition, the etchant composition of the present disclosure includes a chelating agent which helps the dissolution of molybdenum atoms by chemically bonding or physically bonding to molybdenum atoms and/or ions in the molybdenum layer. The chelating agent may be attached to the surface of molybdenum in the molybdenum monolayer to reduce the etch rate, or may function as an etching suppressor. In this case, the etchant composition is coordinate-covalent bonded to the molybdenum atom on the surface of the molybdenum layer to be etched, to reduce the reaction site of the molybdenum atoms, thereby suppressing the etching of the molybdenum.

However, actually, the etchant composition does not merely function as the etching suppressor to reduce the etch rate, with respect to the molybdenum pattern having various structures as shown in the molybdenum layer used in the integrated circuit device, but easily dissolves molybdenum ions oxidized with a lower oxidation state before the molybdenum ions oxidized with the lower oxidation state is changed to be a full oxidation state which is a higher oxidation state. Accordingly, since the chelating agent is contained in the etchant composition according to the embodiments of the present disclosure, the etch rate for the molybdenum layer may be additionally controlled. Accordingly, as the etch rate may be easily controlled, the etching is performed in a uniform etch amount regardless of positions of the molybdenum layer. Accordingly, when the etchant composition according to an embodiment of the present disclosure is used to etch the molybdenum layer used in the integrated circuit device to be described later, the chelating agent may limit and/or minimize the difference in the dissolution rate of the molybdenum layer at etch position of the molybdenum layer. For example, when the molybdenum layer is etched in a vertical direction perpendicular to a surface of a specific substrate, the chelating agent may reduce the difference in dissolution rate between upper and lower sides of the substrate surface. Accordingly, when the molybdenum layer is etched in the vertical direction and when the molybdenum is easily dissolved by the chelating agent, the etchant composition is easily moved even between the upper and lower sides of the substrate surface, such that the etching amount is uniformly maintained at the upper and lower sides of the substrate surface.

The etchant composition according to the related art includes one type of oxidizing agent having higher reactivity to etch molybdenum. However, when the oxidizing agent having the higher reactivity is used according to the related art, the difference in etch rate between positions may be inevitably made in the vertical direction, due to the structure of the molybdenum layer. Accordingly, the etching profile is deteriorated to cause the process efficiency. However, according to an embodiment of the present disclosure, the etchant composition includes two types of oxidizing agents different from each other in reactivity to etch the molybdenum, such that the etching is uniformly performed regardless of positions, thereby enhancing the etching profile.

According to an embodiment of the present disclosure, water is not contained in the etchant composition. Even if water is contained in the etchant composition, less than 0.5 wt % of water, which is an excessively smaller amount of water, may be contained, based on the total amount of the etchant composition. As described above, the content of water is suppressed as much as possible in the etchant composition. Accordingly, when the molybdenum layer is etched using the etchant composition, a material, such as molybdenum dioxide, which is difficult to be dissolved by the inorganic acid, may be limited and/or prevented from being formed. Accordingly, in the process of etching the molybdenum layer, an undesired by-product may be limited and/or prevented from being made.

Accordingly, the etchant composition according to an embodiment of the present disclosure is used to etch the molybdenum layer in the fabricating process of the integrated circuit device, thereby simplifying the fabricating process of the integrated circuit device. Accordingly, the reliability of the integrated circuit device maybe improved.

According to an embodiment of the present disclosure, a target to be etched using the etchant composition is a molybdenum layer provided on the surface of the substrate of the electronic device. In addition, the etchant composition may be used to fabricate electrodes, wirings, and other conductive patterns including molybdenum. In particular, according to an embodiment of the present disclosure, the etchant composition may be used to form a wiring using a molybdenum layer in the process of fabricating a three-dimensional VNAND flash memory device among integrated circuit devices of the electronic device.

Since the VNAND flash memory device includes a plurality of word lines overlapped with each other and stacked on each other in multiple layers, the word lines may be formed using a molybdenum layer. As compared to word lines formed of metal, such as tungsten, the word lines formed using the molybdenum layer have a shorter mean free path of electrons and higher thermal stability. In addition, surface scattering is reduced with respect to the bulk resistivity. However, molybdenum is vulnerable to oxidation, unlike conventional metal, such as tungsten. Accordingly, when the wiring is formed, the etching degree is difficult to be restricted due to the faster etch rate for the general etchant composition. Even after the molybdenum is etched, residues may be produced. When the molybdenum layer is etched using the etchant composition according to an embodiment of the present disclosure, the etch rate may be easily controlled, and the etching degree may be easily controlled. Accordingly, the recess degree may be easily controlled at a specific position, and the residues may be limited and/or prevented from being produced.

The etchant composition according to an embodiment of the present disclosure may be used to fabricate electrodes, wirings, and other conductive patterns including molybdenum constituting components of various electronic devices. Especially, the etchant composition according to an embodiment of the present disclosure may be used to pattern the molybdenum layer in a specific shape.

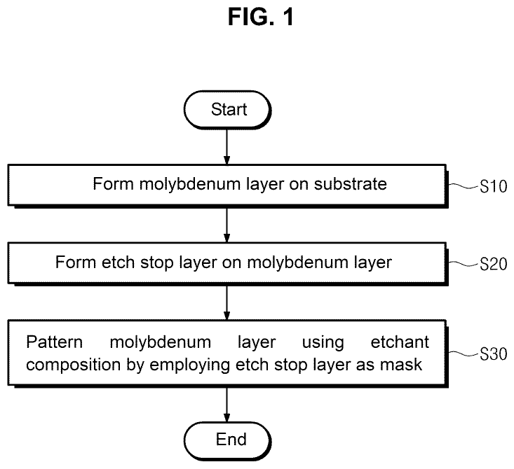

FIG. 1 is a flowchart illustrating a method for patterning a molybdenum layer according to an embodiment of the present disclosure.

Referring to FIG. 1, the method for patterning the molybdenum layer includes forming the molybdenum layer on a substrate (S10), forming an etch stop layer on the molybdenum layer (S20), and etching the molybdenum layer by using the above-described etchant composition and employing the etch stop layer as a mask such that the molybdenum layer is etched by the above-described etchant composition and patterned (S30).

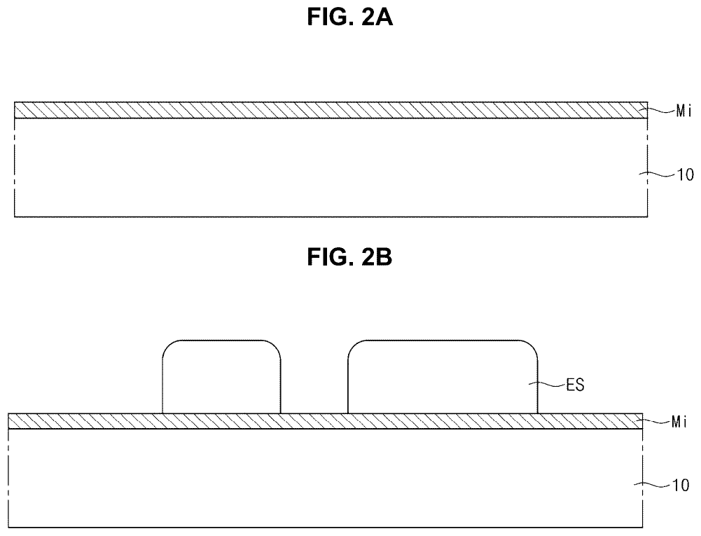

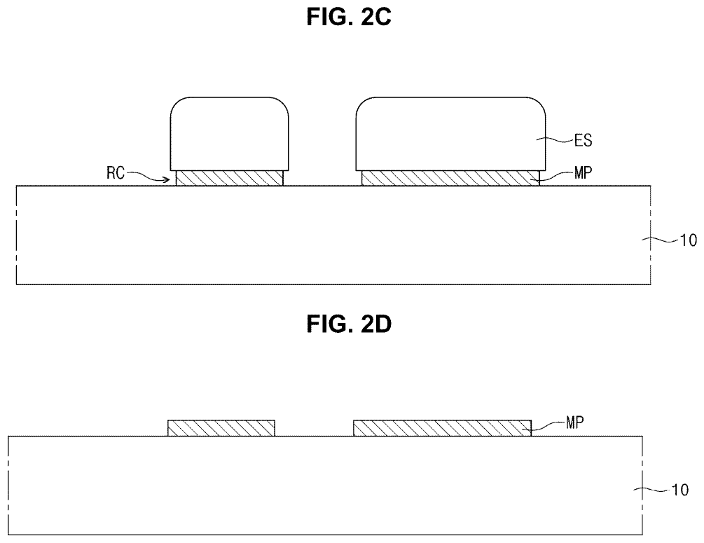

FIGS. 2A to 2D are cross-sectional views sequentially illustrating the method for patterning the molybdenum layer Mi of FIG. 1.

Referring to FIG. 2A, the molybdenum layer Mi is formed on the substrate 10.

The substrate 10, which is used for various electronic devices, may include a metal substrate, a glass substrate, or a plastic substrate, in addition to a semiconductor substrate including a semiconductor material, and the type of the substrate 10 is not limited thereto. The semiconductor substrate may include an elemental semiconductor, such as Si, or Ge, or a compound semiconductor, such as silicon carbide (SiC), gallium arsenide (GaAs), indium arsenide (InAs), or indium phosphate (InP), but the present disclosure is not limited thereto.

The molybdenum layer Mi may be formed through various methods such as atomic layer deposition, chemical vapor deposition, or physical vapor deposition, and the type thereof is not limited.

Referring to FIG. 2B, an etch stop layer ES is formed on the molybdenum layer Mi of the substrate 10. The shape of a region for forming the etch stop layer ES may be determined depending on the shape of the molybdenum layer Mi to be formed.

The etch stop layer ES is to limit and/or prevent the molybdenum layer Mi, which is disposed under the etch stop layer ES, from being etched, but the present disclosure is not limited thereto. The etch stop layer ES may be, for example, a photoresist layer, an organic or inorganic insulating layer, or the stack structure of the organic/inorganic insulating layer, and the photoresist layer. The etch stop layer ES may be selected from materials having an etch ratio different from the etch ratio of the molybdenum layer Mi with respect to the etchant composition.

Referring to FIG. 2C, a portion, which is exposed, of the molybdenum layer Mi is etched by the etchant composition. In this case, since the molybdenum layer Mi and the etchant composition do not make contact with each other on at a region having the etch stop layer ES, a remaining region of the molybdenum layer Mi except for the region having the etch stop layer ES is etched to form the molybdenum layer pattern MP. In addition, the edge of the region having the etch stop layer ES is exposed to the etchant composition. Accordingly, a recess RC may be formed at a lower portion of the edge of the etch stop layer ES, inwardly from the etch stop layer ES. The recessed degree of the recess in the etch stop layer ES may vary depending on the etching amount of the etchant composition. When the etch rate is excessively high, the recessed degree of the recess RC is difficult to control. When the etch rate is excessively low, a time taken to realize the desired recessed degree is increased, so the process efficiency is degraded. Accordingly, the etch rate for the molybdenum layer Mi by the etchant composition may be a specific rate. For example, the etch rate for the molybdenum layer Mi by the etchant composition may be less than 20 Å/min. For example, the etch rate for the molybdenum layer Mi by the etchant composition may be selected in the range from about 0.5 Å/min to about 15 Å/min, or from the range about 3 Å/min to about 14 Å/min.

The etch stop layer ES provided on the molybdenum layer Mi, which is patterned, may be removed thereafter, or may stay on the molybdenum layer Mi without being removed. FIG. 2D illustrates that the etch stop layer ES is removed. As illustrated in FIG. 2D, the etch stop layer ES may be removed through various schemes, such as a strip scheme, an annealing scheme, or plasma treatment.

The molybdenum layer may be formed in various shapes using the etchant composition according to an embodiment of the present disclosure, through the above method. For example, a molybdenum pattern may be formed, in which the molybdenum layers extend in a horizontal direction while being stacked and spaced apart from each other in the vertical direction.

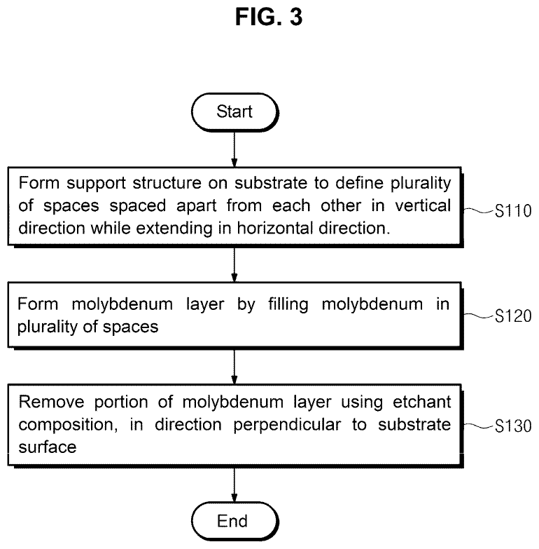

FIG. 3 is a flowchart illustrating a method for forming the molybdenum pattern according to an embodiment of the present disclosure.

Referring to FIG. 3, the method may include forming, on a substrate, a support structure to define a plurality of spaces spaced apart from each other in the vertical direction while extending in the horizontal direction (S110), forming the molybdenum layer by filling molybdenum in the plurality of spaces (S120), and then removing a portion of the molybdenum layer using the etchant composition, in the vertical direction perpendicular to the substrate surface (S130).

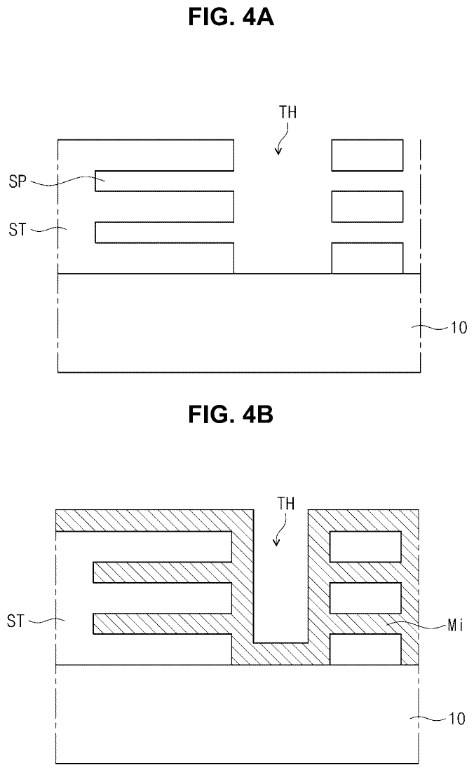

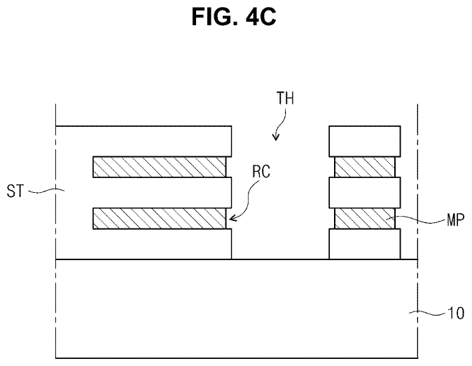

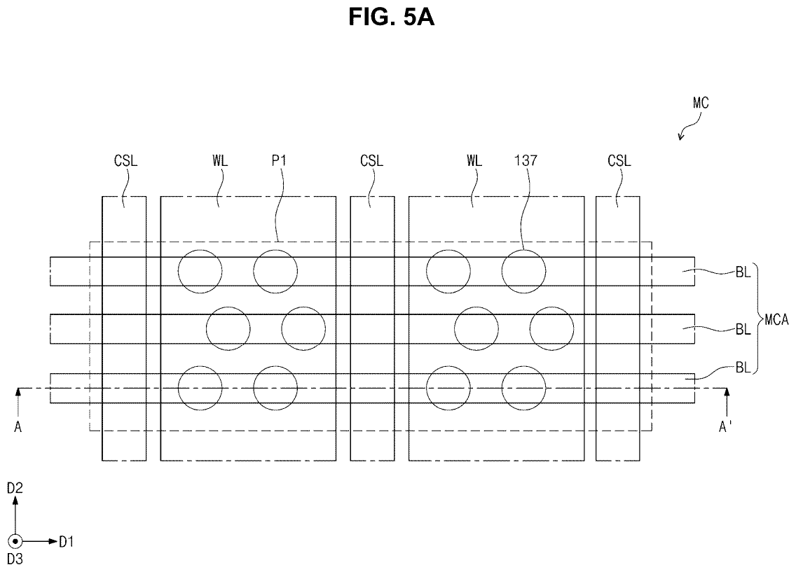

FIGS. 4A to 4C are cross-sectional views sequentially illustrating the method for forming the molybdenum pattern of FIG. 3.

Referring to FIG. 4A, a support structure ST is formed on the surface of a substrate 10 to correspond to the molybdenum pattern to be formed. The support structure ST, which is to provide the plurality of spaces, may be formed, such that the molybdenum layer Mi is formed in the plurality of spaces SP. For example, when the molybdenum layer patterns MP spaced apart from each other in the vertical direction are formed, the support structure ST may have the plurality of spaces SP spaced apart from each other in the vertical direction. The support structure ST may have a through hole TH opening upward while passing through the plurality of spaces SP in the vertical direction.

The support structure ST may be an insulating layer including an insulating material, a conductive layer including a conductor (e.g., a metal layer), or a complex layer formed by covering the insulating layer on the conductive layer. The support structure ST may include a material which is not etched by the etchant composition according to an embodiment of the present disclosure. In other words, the support structure ST may include a material allowing the etch rate for the molybdenum layer by the etchant composition according to an embodiment of the present disclosure to be higher. For example, the support structure ST may be an insulating layer including an insulating material, rather than a metal layer, or a complex layer having a surface corresponding to the insulating layer by coating the metal layer with the insulating material. The insulating layer may include, for example, a silicon oxide layer, a silicon nitride layer, or the combination thereof, but the present disclosure is not limited thereto.

The plurality of spaces SP spaced apart from each other in the vertical direction may be formed by forming a plurality of sacrificial layers spaced apart from each other in the vertical direction and etching and removing the sacrificial layers. After the sacrificial layers are etched, the plurality of spaces SP may be formed in place of the plurality of sacrificial layers. However, the method for forming the plurality of spaces SP spaced apart from each other in the vertical direction is not limited thereto. For example, the plurality of spaces SP may be formed in another method.

Referring to FIG. 4B, the molybdenum layer Mi filling the plurality of spaces SP formed by the support structure ST may be formed. The molybdenum layer Mi may be formed in the plurality of spaces through various methods, and may be formed, for example, through an atomic layer deposition process. In this case, the molybdenum layer Mi may cover sidewalls of the support structure ST while filling the spaces SP extending in the horizontal direction.

Referring to FIG. 4C, a portion of the molybdenum layer Mi may be removed by using the etchant composition according to an embodiment of the present disclosure. The portion of the molybdenum layer Mi is removed through the through hole TH in the direction perpendicular to the surface of the substrate 10 to divide the molybdenum layer Mi provided in the plurality of spaces SP spaced apart from each other. In other words, portions, which formed on the top surface of the support structure ST and formed on the sidewalls facing each other to define the through hole TH, of the molybdenum layer Mi may be removed. In this case, the molybdenum layer Mi, which is adjacent to the through hole TH, exposed by the etchant composition is additionally etched. Accordingly, the molybdenum layer Mi may have the recess recessed inward from the sidewalls of the support structure ST.

After the etching process is performed, a molybdenum layer pattern MP in which the molybdenum layer is formed only in the plurality of spaces SP, is formed. As the molybdenum layer is removed from the sidewall of the through hole TH in the support structure ST, the molybdenum layer patterns MP stacked in the vertical direction may be separated from each other.

In this case, when the molybdenum layer Mi is etched to have a recess RC, the molybdenum layer patterns stacked in the vertical direction may be completely separated from each other. When the molybdenum layer Mi is etched such that the recess RC is not formed, a portion of the molybdenum layer Mi, which is not etched, may remain on the sidewalls of the support structure ST. The molybdenum layer patterns MP stacked in the vertical direction may be electrically connected and shorted by a portion of the molybdenum layer remaining on the sidewalls.

When the portion of the molybdenum layer Mi is removed using the etchant composition according to an embodiment of the present disclosure, the recessed degree of the recess in the etch stop layer ES may vary depending on the etching amount of the etchant composition. When the etch rate is excessively high, the recessed degree of the recess may be difficult to control. When the etch rate is excessively low, a time taken to realize the desired recessed degree is increased, so the process efficiency is degraded. Accordingly, the etch rate for the molybdenum layer Mi by the etchant composition may be controlled to be a specific rate. For example, the etch rate for the molybdenum layer Mi by the etchant composition may be less than 20 Å/min. For example, the etch rate for the molybdenum layer Mi by the etchant composition may be selected in the range from about 05 Å/min to about 15 Å/min, or from the range about 3 Å/min to about 14 Å/min.

When the process of removing the portion of the molybdenum layer Mi is performed by using the etchant composition, the process temperature may be selected in the range from a temperature higher the melting point of each material and equal to or less than a normal temperature, based on the melting point of the material. For example, the process temperature for etching the molybdenum layer Mi may be selected in the range from about 10° C. to about 50° C., for example, about 15° C. to about 45° C., or about 30° C. to about 40° C. According to an embodiment of the present disclosure, a thermostat may be used to remove the portion of the molybdenum layer Mi by using the etchant composition under a constant temperature.

As described above, the molybdenum layer Mi may be patterned in various shapes through the above method according to an embodiment of the present disclosure. The wiring, the electrode, and other conductive components of the electronic device may be formed through the method for patterning the molybdenum layer Mi. For example, according to an embodiment of the present disclosure, the molybdenum layer Mi is patterned by using the etchant composition according to an embodiment of the present disclosure, thereby forming the integrated circuit device of the electronic device.

Hereinafter, after describing an integrated circuit device of the electronic device realized by patterning the molybdenum layer using the etchant composition according to an embodiment of the present disclosure, the method for fabricating the integrated circuit device will be described.

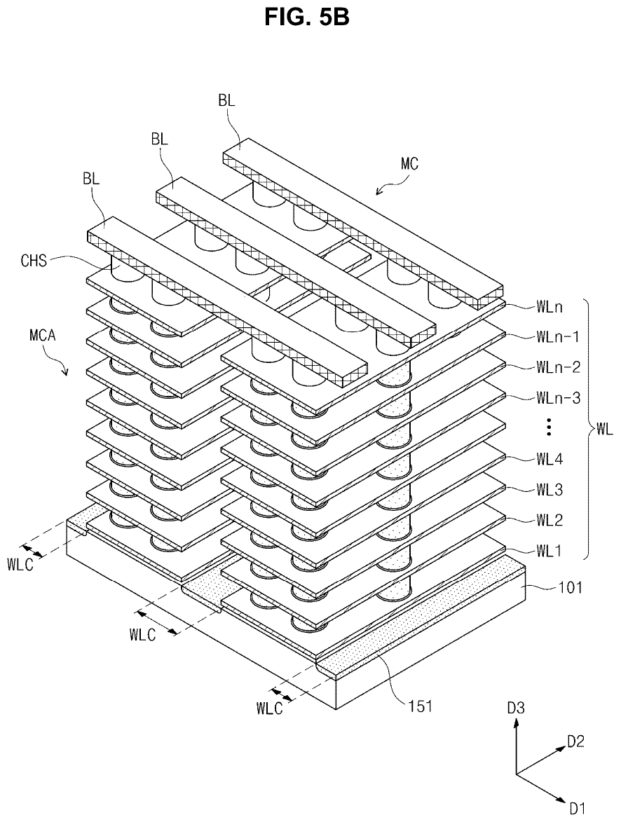

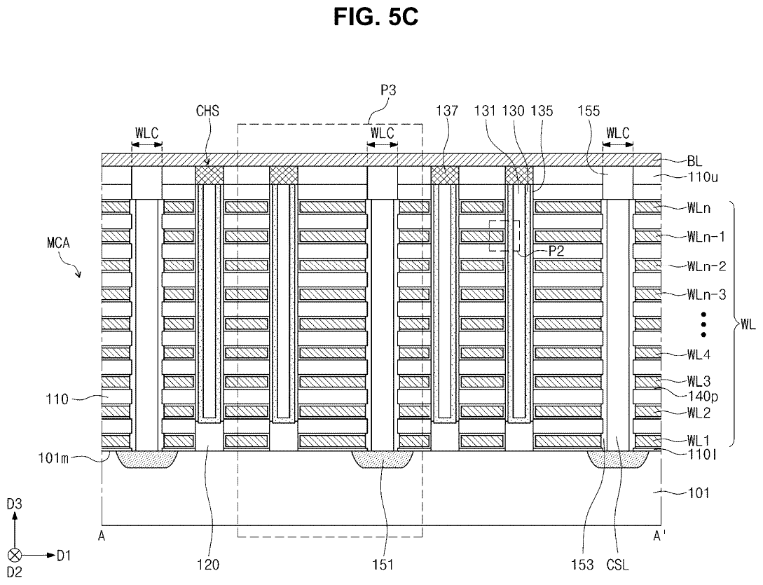

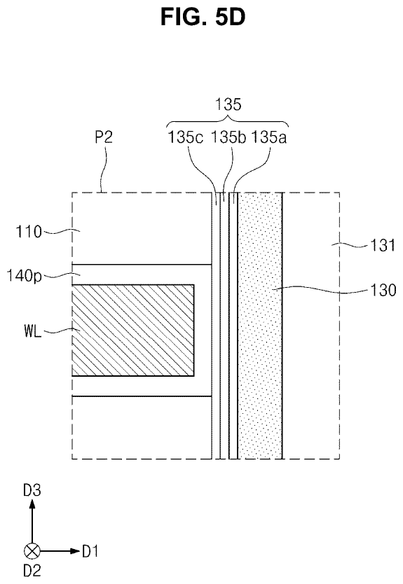

FIGS. 5A to 5D are views illustrating the integrated circuit device realized through the method for fabricating the integrated circuit device according to an embodiment of the present disclosure. In detail, FIGS. 5A to 5D are views illustrating a VNAD memory device.

FIG. 5A is a plan view of main components of the integrated circuit device according to an embodiment, and FIG. 5B is a schematic perspective view illustrating main components of a region marked by ‘P1’ of FIG. 5A. FIG. 5C is a schematic vertical cross-sectional view taken along line A-A′ of FIG. 5A, and FIG. 5D is an enlarged cross-sectional view illustrating region P2 of FIG. 5C.

Referring to FIGS. 5A to 5C, the integrated circuit device includes a memory cell array region MCA formed on the substrate 101. The memory cell array region has components including a plurality of word lines WL, a plurality of bit lines BL, and a channel structure CHS connected to the plurality of word lines WL and the plurality of bit lines BL.

The substrate 101 may have a main surface 101m extending in a first direction D1 (e.g., an x-direction) and a second direction D2 (e.g., a y-direction). The substrate 101 may be a semiconductor substrate, and may include, for example, Si, Ge, or SiGe. According to embodiments, the substrate may include a silicon-on-insulator (SOI) substrate or a germanium-on-insulator (GeOI) substrate. The memory cell array region MCA of the integrated circuit device includes a plurality of memory cells MC.

A plurality of word lines WL, each of which includes WL1, WL2, . . . , Wn-1, and Wn, are provided on in the memory cell region MCA of the substrate 101 while extending in parallel to an extension direction of a main surface 101m of the substrate, and may be formed to be overlapped with each other while being spaced apart from each other in a third direction D3 (e.g., a z-direction) perpendicular to the main surface 101m of the substrate. The plurality of word lines WL, each of which includes a plurality of word lines WL1, WL2, . . . , Wn-1, and Wn, are spaced apart from each other by a specific distance due to a plurality of word line cut regions WLC and are repeatedly arranged in a first direction D1 parallel to the extending direction of the main surface 101m of the substrate. The plurality of word line cut regions WLC define the widths of word lines WL, each of which includes a plurality of word lines WL1, WL2, . . . , Wn-1, and Wn, in the first direction D1, and may extend in parallel to the second direction D2 perpendicular to the first direction D1 along the surface (i.e., a plan formed in the second direction D2 and the third direction D3) perpendicular to the main surface 101m of the substrate.

A plurality of common source regions 151 may extend on the substrate 101 in the extension direction (that is, the second direction D2) of the word line cut region WLC. According to embodiments, the plurality of common source regions 151 may be an impurity region heavily doped with N-type dopants. The plurality of common source region 151 may be used as source regions to apply a current to a vertical-type memory cell. The plurality of common source lines CSL may extend in an extension direction (that is, the second direction D2) of the word line cut region WLC, on the common source region 151. The plurality of common source line CSL may be formed to fill a portion of the word line cut region WLC at one side of the word lines WL, each of which includes a plurality of word lines WL1, WL2, . . . , Wn-1, and Wn L.

The plurality of w word lines WL, each of which includes a plurality of word lines WL1, WL2, . . . , Wn-1, and Wn may be sequentially sacked between two adjacent word line cut regions WLC. Although not illustrated, at least one grounding selection line and at least one string selection line may be provided on a lower portion of the plurality of word lines WL and on an upper portion of the plurality of word lines WL, respectively, in the form similar to that of the plurality of word lines WL. The following description will be made while focusing on the plurality of word lines WL for the illustrative purpose.

The plurality of word lines WL may be formed of a molybdenum layer.

An insulating layer 110 may be interposed between the substrate 101 and each of which includes the plurality of word lines WL1, WL2, . . . , Wn-1, and Wn. The insulating layer 110 may include a silicon insulating layer.

A dielectric layer pattern 140p is provided between the word line WL and the insulating layer 110 adjacent to each other. The dielectric layer pattern 140p is provided in the form of surrounding the word line WL, but is not provided on the side surface of the word line WL adjacent to the word line cut region WLC. The dielectric layer pattern 140p may include a higher dielectric material having a dielectric constant higher than that of silicon oxide. For example, the dielectric layer pattern 140p may include an aluminum dielectric layer, a hafnium dielectric layer, a zirconium dielectric layer, or a tantalum dielectric layer.

A plurality of channel structures CHS may extend in a direction (the third direction D3) perpendicular to the main surface 101m of the substrate, through the plurality of word lines WL, each of which includes a plurality of word lines WL1, WL2, . . . , Wn-1, and Wn and the plurality of insulating layer 110, in the memory cell array MCA. The channel structures CHS may include the plurality of channel regions 130, and the plurality of channel regions 130 may be spaced apart from each other by a specific distance in the first direction D1 and the second direction D2. The arrangement of the plurality of channel regions 130 illustrated in FIG. 5C is provided only for the illustrative purpose. The arrangement of the plurality of channel regions 130 may variously deformed and changed.

The plurality of channel regions 130 may be connected to a plurality of bit lines BL, respectively. The plurality of channel regions 130 may be repeatedly formed at a specific pitch. The plurality of channel regions 130 may include doped polysilicon, undoped polysilicon, metal, conductive metal nitride, silicide, carbon nanotube, graphene, or the combination thereof. Each of the plurality of channel regions 130 may have a cylindrical shape.

According to an embodiment of the present disclosure, the inner space of each of the plurality of channel regions 130 may be filled with a buried insulating layer 131. The buried insulating layer 131 may include silicon oxide, silicon nitride, silicon oxynitride, or the combination thereof.

According to some embodiments, the plurality of channel regions 130 may have a pillar structure, which is different from those illustrated in FIGS. 5C. In this case, the buried insulating layer 131 may be omitted.

A gate insulating layer 135 may be interposed between each of the plurality of channel regions 130 and the plurality of word lines WL, each of which includes the word lines WL1, WL2, . . . , Wn-1, and Wn.

FIG. 5D is an enlarged cross-sectional view illustrating a partial region P1 of FIG. 5C.

Referring to FIG. 5D, the gate insulating layer 135 may include a tunnel insulating layer 135a, a charge storage layer 135b, and a blocking insulating layer 135c sequentially stacked toward the word line WL from the channel region 130.

The tunnel insulating layer 135a may include silicon oxide, hafnium oxide, aluminum oxide, zirconium oxide, or tantalum oxide.

The charge storage layer 135b is a region for storing electrons tunneling the tunnel insulating layer 135a from the plurality of channel regions 130, and may include silicon nitride, boron nitride, silicon boron nitride, or polysilicon doped with impurities.

The blocking insulating layer 135c may include silicon oxide, silicon nitride, or metal oxide having a higher insulation ratio than silicon oxide. The metal oxide may include hafnium oxide, aluminum oxide, zirconium oxide, tantalum oxide, or the combination thereof. According to some embodiments, the blocking insulating layer 135c may include a high dielectric layer having a higher dielectric constant than that of the silicon insulating layer.

Although FIGS. 5C and 5D illustrate that the gate insulating layer 135 has the shape of extending along the outer sidewall of the channel region 130, an embodiment of the present disclosure is not limited thereto. For example, at least some of the blocking insulating layer 135c, the charge storage layer 135b, and the tunnel insulating layer 135b constituting the gate insulating layer 135 may extend along the bottom surface, the top surface, and the sidewall of the word line WL to cover the surface, which faces the channel region 130, of the word line WL, and surfaces, which face the insulating layer 110, of the word line WL.

Referring back to FIGS. 5A to 5C, an insulating spacer 153 may be formed in the word line cut region WLC to cover the sidewall of the common source line CSL. The insulating spacer 153 may electrically insulate the plurality of word lines WL, each of which includes a plurality of word lines WL1, WL2, . . . , Wn-1, and Wn from the common source line CSL. The common source line CSL may include metal, such as tungsten, copper, or aluminum; a conductive metal nitride, such as titanium nitride, or tantalum nitride; transition metal such as titanium or tantalum, or the combination thereof. The insulating spacer 153 may include silicon oxide, silicon nitride, silicon oxynitride, or a low insulating material.

A capping insulating layer 155 may be formed on the common source line CSL in the word line cut region WLC. The capping insulating layer 155 may include a silicon insulating layer, a silicon nitride layer, a silicon oxynitride layer, or the combination thereof.

A plurality of bit line contact pads 137 may be formed on the plurality of channel regions 130. The plurality of bit line contact pads 137 may include polysilicon doped with impurities, metal, conductive metal nitride, or the combination thereof. When the bit line contact pad 137 includes metal, such as tungsten, nickel, cobalt, or tantalum, the present disclosure is limited thereto.

A plurality of bit lines BL may be formed on the plurality of bit line contact pads 137. According to some embodiments, as illustrated in FIG. 5C, the plurality of bit lines BL may make direct contact with top surfaces of the plurality of bit line contact pads 137. According to some embodiments, the plurality of bit lines BL may be connected to the plurality of bit line contact pads 137 through the contact plug (not illustrated), which is different from those illustrated in FIG. 5C. The plurality of bit lines BL may extend in the direction (the first direction; D1) parallel to the main surface 101m of the substrate. The plurality of bit lines BL may include polysilicon doped with impurities, metal, conductive metal nitride, or the combination thereof.

An upper insulating layer 110u may be formed between the stack structure including the plurality of word lines WL, each of which includes a plurality of word lines WL1, WL2, . . . , Wn-1, and Wn and the bit line BL.

Hereinafter, the method for fabricating the integrated circuit device having the above-described structure will be described.

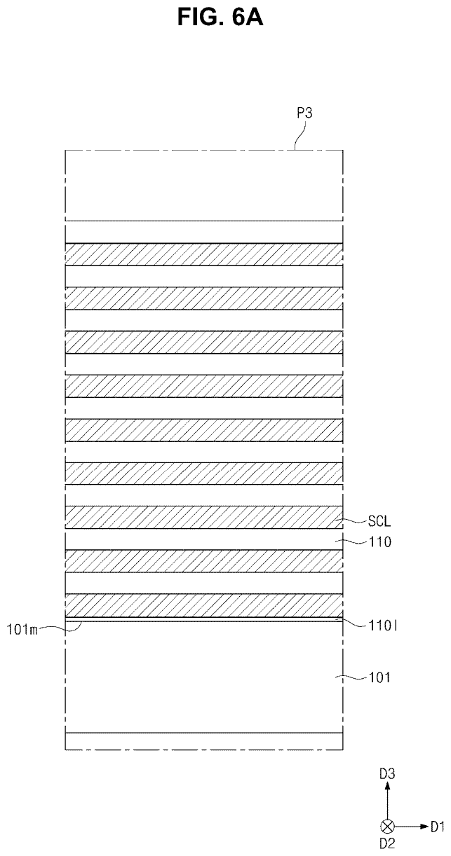

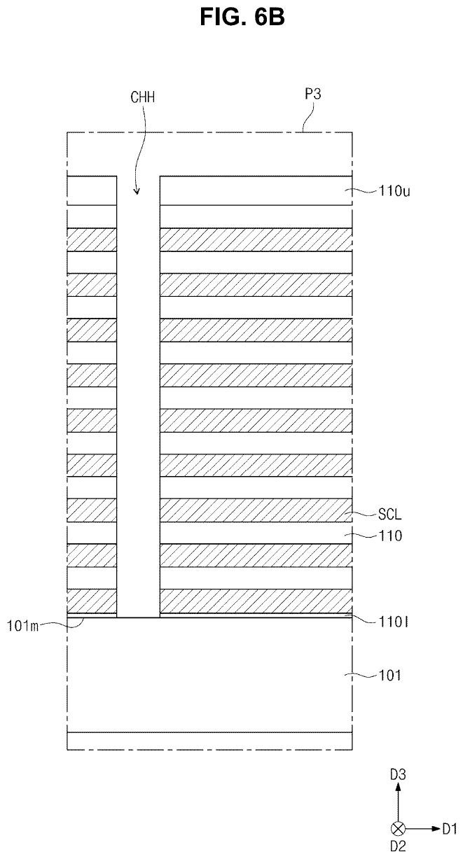

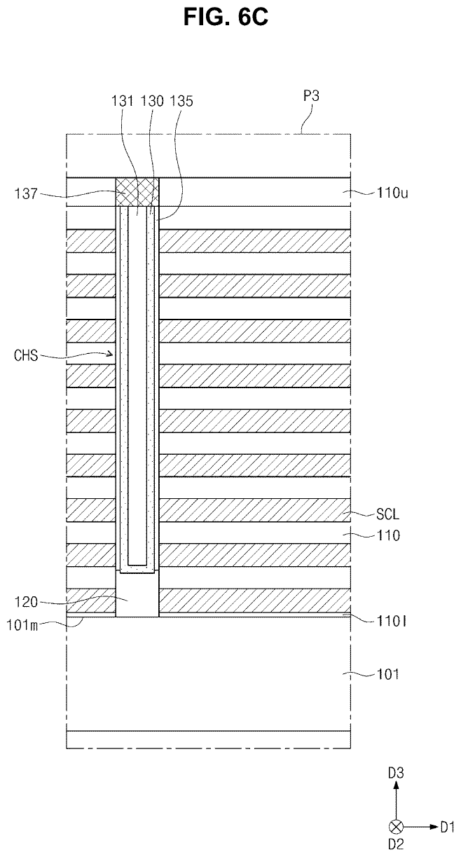

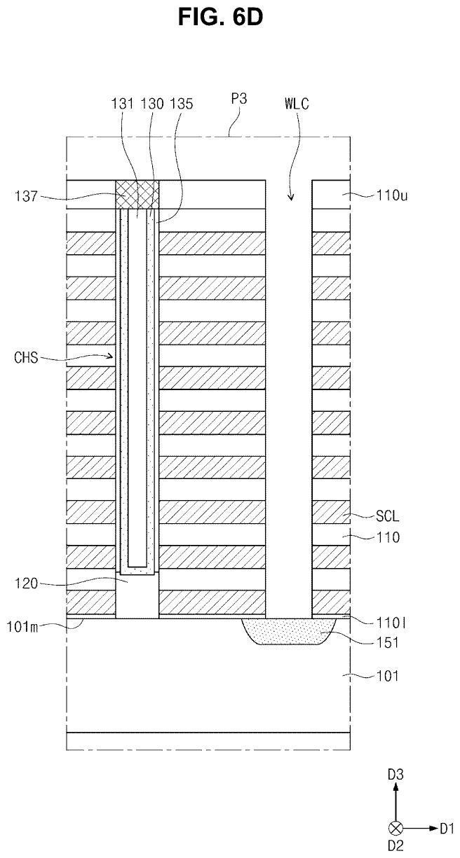

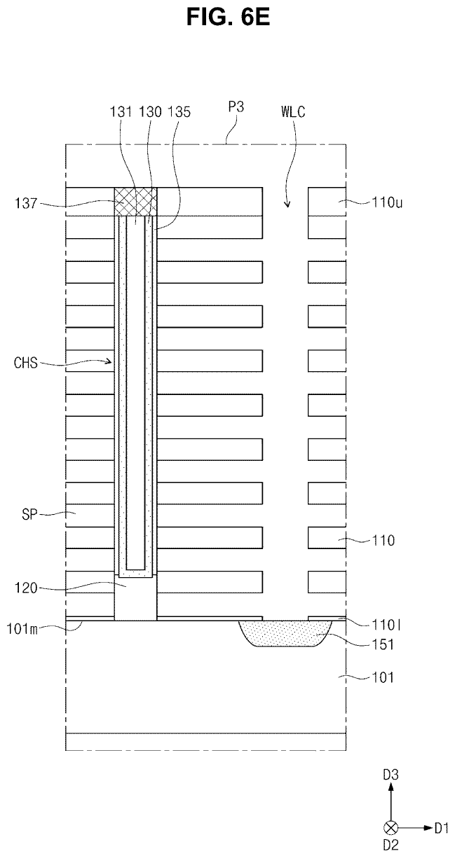

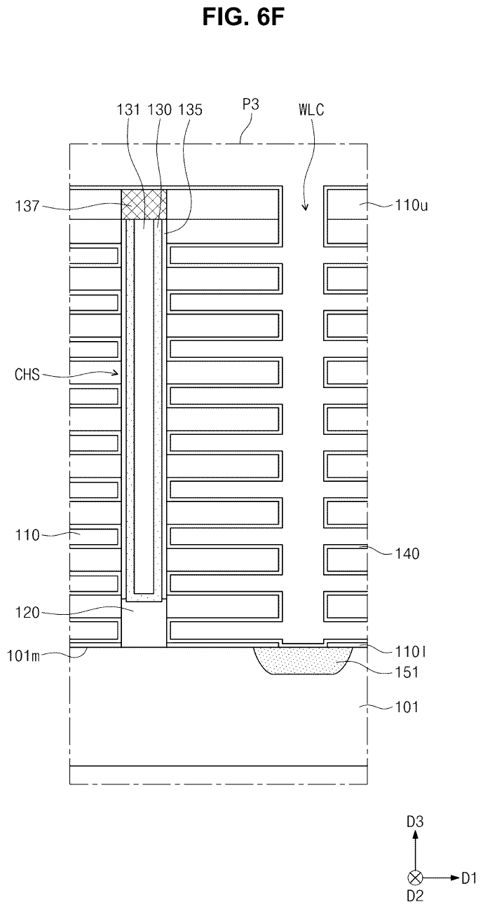

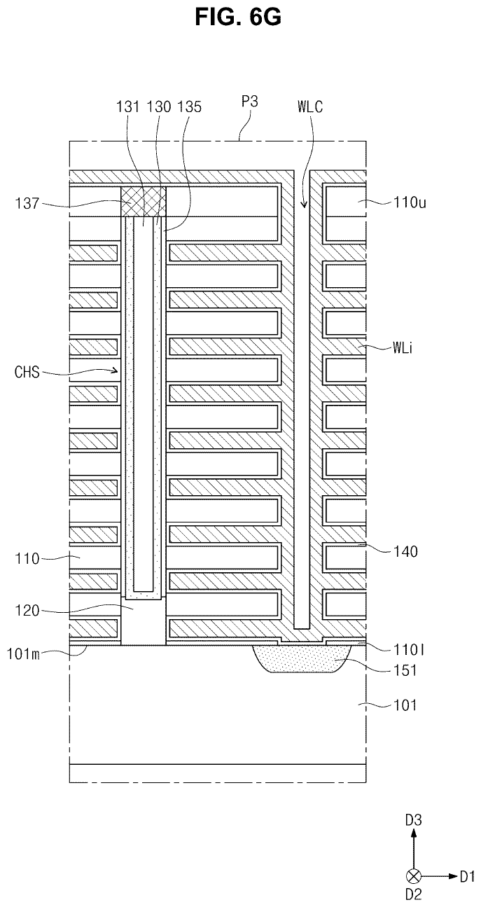

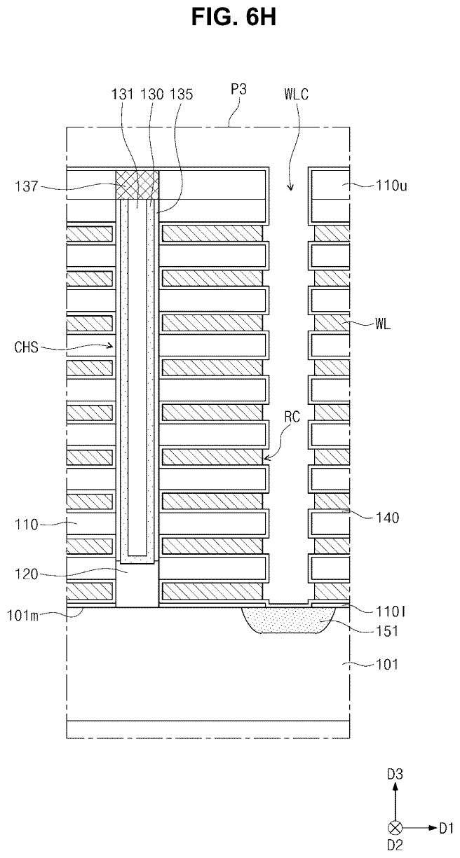

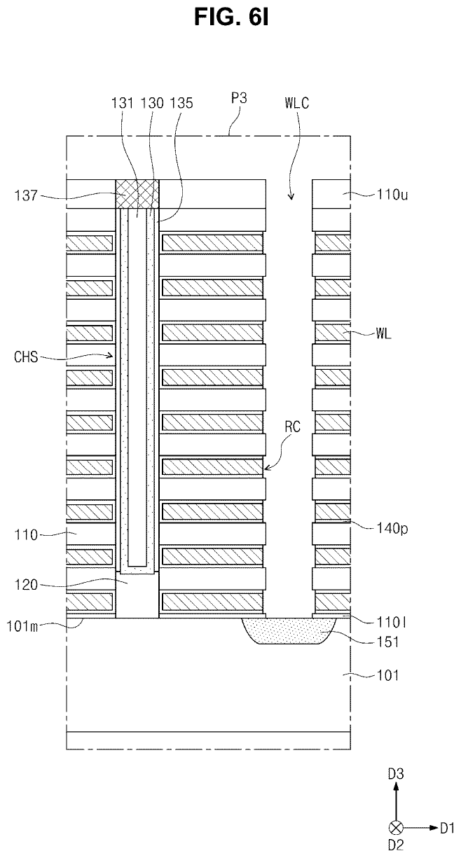

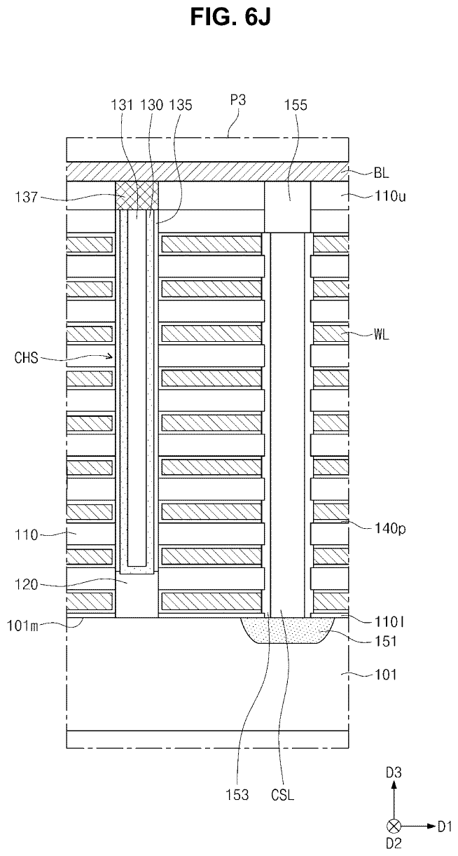

FIGS. 6A to 6J are cross-sectional views illustrating a region corresponding to ‘P3’ of FIG. 5C according to a process sequence to describe the method for fabricating the integrated circuit device according to embodiments of the present disclosure. The method for fabricating the integrated circuit device including a vertical NAND (VN) flash memory having a structure in which a plurality of word lines are stacked to be overlapped with each other in the vertical direction will be described as an example with reference to FIGS. 6A to 6J.

Referring to FIG. 6A, a lower insulating layer 1101 is provided on the main surface 101m of the substrate, and a sacrificial layer SCL and the insulating layer 110 are alternatively stacked on the lower insulating layer 1101 in the third direction D3.

The lower insulating layer 110, which is provided to be closest to the substrate 101, of the plurality of insulating layers may be formed in a single layer including a silicon insulating layer. The lower insulating layer 1101 may have a thickness thinner than that of another insulating layer 110.

According to an embodiment of the present disclosure, the insulating layers 110 and the sacrificial layers SCL may include materials having mutually different etch rates under a specific condition. For example, the sacrificial layers SCL may include a material having a higher etch rate under the specific etching condition, as compared to the insulating layers 110. For example, according to an embodiment of the present disclosure, the plurality of sacrificial layers SCL may include a silicon nitride, and the plurality insulating layers 110 may include a silicon insulating layer.

The plurality of insulating layers 110 and the plurality of sacrificial layers SCL may be formed through a chemical vapor deposition (CVD) process, a plasma enhanced CVD (PECVD) process or an ALD process.

A structure, in which the plurality of insulating layers 110 and the plurality of sacrificial layers SCL are alternately stacked one by one, may be necessary to form a memory stack. The plurality of sacrificial layers SCL may be removed in the subsequent process, thereby providing a space for forming the plurality of word lines WL included in the memory stack. Although not illustrated, the insulating layer 110 formed right on the first sacrificial layer SCL, which is first positioned from the substrate 101, among the plurality of sacrificial layers SCL may have a thickness thicker than the thickness of the insulating layer 110 positioned at another position.

In the stack structures in which the plurality of insulating layers 110 and the plurality of sacrificial layers SCL are alternately stacked one by one, the plurality of insulating layers 110 and the plurality of sacrificial layers SCL may be stacked to be overlapped with in the vertical direction (the third direction D3). For example, the insulating layers 110 and the sacrificial layers SCL may be stacked in at least 50 layers, at least 100 layers, or at least 600 layers. The number of layers stacked on each other may vary depending on the specification of a memory stack including the word lines.

Referring to FIG. 6B, after an upper insulating layer 110u is formed on a result structure of FIG. 6A, the plurality of insulating layers 110 and the plurality of sacrificial layers SCL are anisotropic-etched using the upper insulating layer 110u as an etching mask, thereby forming a channel hole CHH. The upper insulating layer 110u may be provided in a single layer or a multi-layer.

The channel hole CHH may pass through the structure including the plurality of insulating layers 110 and the plurality of sacrificial layers SCL in the vertical direction (the third direction D3). The channel hole CHH may expose the top surface of the substrate 101.

Although the drawing of the present disclosure illustrates that the channel hole CHH has a uniform width in the vertical direction, this is provided only for the illustrative purpose. For example, the width of the channel hole CHH in the horizontal direction may be decreased toward the substrate 101.

Referring to FIG. 6C, a selective epitaxial growth process may be performed using the substrate 101, which is exposed on a bottom of the channel hole CHH, as a seed, thereby forming a semiconductor pattern 120 partially filling the channel hole CHH. The top surface of the semiconductor pattern 120 may be positioned at a level higher than a level of a top surface of the sacrificial layer SCL, which is closest to the substrate 101, among the plurality of sacrificial layers SCL. According to an embodiment of the present disclosure, the semiconductor pattern 120 may include a semiconductor layer doped with impurities. For example, the semiconductor pattern 120 may include a Si layer doped with impurities or a Ge layer doped with the impurities.

A channel structure CHS may be formed in the channel hole CHH. The channel structure CHS may include a gate insulating layer 135, a channel region 130, and a buried insulating layer 131, and a bit line contact pad 137 filling an upper portion of an entrance of the channel hole CHH. The gate insulating layer 135 may include a blocking insulating layer 135c, a charge storage layer 135b, and a tunnel insulating layer 135a. Each of the gate insulating layer 135 and the channel region 130 may have a cylindrical shape.

In the process of forming the blocking insulating layer 135c, the charge storage layer 135b, the tunnel insulating layer 135a, and the channel region 130 in the channel hole CHH, a partial region of the top surface of the semiconductor pattern 120 may be removed, and the top surface of the semiconductor pattern 120 and the channel region 130 may make contact with each other.

According to an embodiment of the present disclosure, the upper insulating layer 110u may remain around the bit line contact pad 137 or may be removed. For example, the top surface of the uppermost insulating layer 110 is exposed by removing the upper insulating layer 110u while forming the blocking insulating layer 135c, the charge storage layer 135b, the tunnel insulating layer 135a, the channel region 130, and the buried insulating layer 131 in the channel hole CHH. Thereafter, a novel insulating layer (not illustrated) is formed to cover the top surface of the uppermost insulating layer 110, and regions, which correspond to the channel hole CHH, of the insulating layer are etched to form the plurality of contact holes. Thereafter, the bit line contact pad 137 may be formed to fill the plurality of contact holes.

Referring to FIG. 6D, the upper insulating layer 110u, the plurality of insulating layers 110, and the plurality of sacrificial layers SCL are anisotropic-etched to form the through hole to expose the substrate 101, in other words, the word line cut region WLC. Then, the impurity ions are implanted into the substrate 101 through the word line cut region WLC, thereby forming the common source region 151.

The word line cut region WLC may be formed through the structure including the plurality of insulating layers 110 and the plurality of sacrificial layers SCL in the vertical direction (that is, the third direction D3) while extending in a line form in the horizontal direction. Accordingly, a common source region 151 may be formed to extend in a line form along the word line cut region WLC.

Referring to FIG. 6E, the plurality of sacrificial layers SCL exposed through the word line cut region WLC may be removed to form the plurality of word line spaces SP between the plurality of insulating layers 110. In this case, remaining components except for the sacrificial layer SCL become the support structure to provide the plurality of word line spaces SP.

The plurality of word line spaces SP may extend in the direction parallel to the main surface 101m of the substrate and may be overlapped with each other in the vertical direction (that is, the third direction D3) perpendicular to the main surface 101m of the substrate. The plurality of word line spaces SP may communicate with the word line cut region WLC. The blocking insulating layer 135c of the channel structure CHS may be exposed through the plurality of word line spaces SP.

Referring to FIG. 6F, the dielectric layer 140 may be formed to conformally cover the surfaces exposed through the plurality of word line spaces SP and the word line cut region WLC.

The dielectric layer 140 may be formed to conformally cover the surface of each of the plurality of insulating layers 110 and the channel structure CHS exposed through the word line cut region WLC and the plurality of word line spaces SP.

Referring to FIG. 6G, a molybdenum layer WLi may be formed to fill remaining spaces of the plurality of word line spaces SP in the result structure of FIG. 6F. The molybdenum layer Wli may be formed to fill spaces, which are defined by the dielectric layer 140, of the plurality of word line spaces SP. In detail, the molybdenum layer Wli may be formed to fill an outside of each of the plurality of word line spaces SP and partially fill the word line cut region WLC. Portions, which are outside each of the plurality of word line spaces SP, of the dielectric layer 140 may cover the sidewall of the plurality of dielectric layers 140 while interposing the dielectric layer 140 between the sidewalls, in the word line cut region WLC.

Referring to FIG. 6H, the etchant composition is applied through the word line cut region WLC in the result structure of FIG. 6G, thereby removing a portion of the molybdenum layer Wli. Accordingly, the plurality of word line spaces SP (see FIG. 6F) is filled on the dielectric layer 140, and the plurality of word lines WL may be obtained with the plurality of molybdenum patterns spaced apart from each other.

The sidewall of the word line WL, which faces the word line cut region WLC, may have a shape recessed, that is, a recess RC, in the horizontal direction from the word line cut region WLC, rather than the sidewall of the dielectric layer 140 facing the word line cut region WLC. Accordingly, the plurality of word lines WL may be firmly separated from each other while being overlapped with each other in the vertical direction (the third direction D3).

The detailed ingredients of the etchant composition have been described above according to embodiments of the present disclosure.

When a portion of the molybdenum layer Wli is removed using the etchant composition, the etch rate of the molybdenum layer Wli by the etchant composition may be lower than 20 Å/min. For example, the etch rate for the molybdenum layer Wli by the etchant composition may be selected in the range from about 0.5 Å/min to about 15 Å/min, or the range from about 3 Å/min to about 14 Å/min.

To control the etch rate for the molybdenum layer Wli by the etchant composition to be in the desired range, the contents of the oxidizing agent and the chelating agent contained in the etchant composition may be adjusted. For example, the oxidizing agent may be adjusted to be in the range from about 0.01 wt % to 20 wt %, based on the 100 wt % which is the total amount of the etchant composition, or the chelating agent may be adjusted to be in the range from 0.0001 wt % to 20 wt %, based on the 100 wt % which is the total amount of the etchant composition. According to an embodiment of the present disclosure, while performing the process of removing a portion of the molybdenum layer Wli using the etchant composition, the process temperature selected in the range from about 20° C. to about 40° C. may be maintained.

According to an embodiment of the present disclosure, when the portion of the molybdenum layer Wli is removed using the etchant composition, the etch rate for portions, which are exposed through the word line cut region WLC, of the molybdenum layer Wli by the etchant composition may be substantially uniform along the vertical distance from the substrate 101. For example, the etch rate for portions, which are exposed through the word line cut region WLC, of the molybdenum layer Wli by the etchant composition may be substantially equal to each other or approximate to each other in a bottom portion, which is closest to the substrate 101, of the word line cut region WLC, an upper portion, which is at an entrance of the word line cut region WLC farthest away from the substrate 101, of the word line cut region WLC, and an intermediate portion of the word line cut region WLC between the bottom portion and the upper portion. In this case, the etch rate of the upper portion, the intermediate portion, and the bottom portion may be controlled by controlling the content of the chelating agent. The content of the chelating agent in the whole etchant composition may be controlled in the range from 0.0001 wt % to 20 wt % to limit and/or minimize the difference in dissolution rate depending on etching positions of the molybdenum layer Wli.

Referring to FIG. 6H, after forming the plurality of word lines WL by etching a portion of the molybdenum layer Wli using the etchant composition according to an embodiment of the present disclosure, the dielectric layer 140 may be exposed through the word line cut region WLC. In this case, while etching the portion of the molybdenum layer Wli using the etchant composition according to an embodiment of the present disclosure, the dielectric layer 140 is not etched by the etchant composition or is etched by the etchant composition in a significantly smaller amount even if the dielectric layer 140 is etched.

Referring to FIG. 6I, portions of the dielectric layer 140, which are exposed, are removed from the result structure of FIG. 6H, thereby forming a plurality of dielectric patterns 140p. After the plurality of dielectric patterns 140p are formed, the sidewall of each of the plurality of insulating layers 110 and a top surface of the common source region 151 may be exposed in the word line cut region WLC.

Referring to FIG. 6J, an insulating spacer 153 and a common source line CSL may be formed in the word line cut region WLC, and a capping insulating layer 155 may be formed in the word line cut region WLC to cover a top surface of the insulating spacer 153 and the common source line CSL.

According to an embodiment of the present disclosure, a metal silicide layer (not illustrated) may be interposed between the common source region 151 and the common source line CSL to decrease a contact resistance. For example, the metal silicide layer may be formed of cobalt silicide, tungsten silicide, or nickel silicide.

A bit line BL may be formed on the capping insulating layer 155 and the bit line contact pad 137.

According to the method for fabricating the integrated circuit device described with reference to FIGS. 6A to 6J, in the process of fabricating the highly-integrated circuit device, the molybdenum layer may be etched in a target etching amount by adjusting the etch rate for the molybdenum layer. In addition, when the molybdenum layer is etched, undesired residues may be limited and/or prevented from being produced. Accordingly, the method for fabricating the integrated circuit device including the molybdenum layer may be simplified, thereby improving the integrated circuit device in reliability.

### Experimental Example 1

The etch rate and the selectivity were measured when the plurality of word lines are formed in a manner for removing a portion of the molybdenum layer using the etchant composition having various compositions, in the method for fabricating an integrated circuit device according to an embodiment of the present disclosure, and the measurement results are shown in Tables 1 and 2.

Experimental examples shown in Tables 1 and 2 were performed under the same condition except for the etchant composition. Table 1 shows embodiments of the etchant composition according to an embodiment of the present disclosure, and Table 2 shows comparison examples having an etchant composition having a composition different from the composition of the etchant composition according to the present disclosure.

As shown in Table 1 and Table 2, the wording “partial etching” refers to that a recess recessed in the horizontal direction from the word line cut region is not formed, even though the word line cut region is etched, and the wording “total etching” refers to that the entire portion of the molybdenum layer is etched. The selectivity indicates the ratio between the etch rate for the bottom portion, which is closest to the substrate, of the word line cut region and the etch rate for the top portion of the entrance of the word line cut region. In the following table, “EDTA” indicates ethylenediaminetetraacetic acid.

TABLE 1

| | Composition of etchant | Temperature | etch rate | Selectivity |
|---|---|---|---|---|
| | composition | (° C.) | (Å/min) | (Top/Bottom) |
| Embodiment 1 | 0.2 wt % of ammonium nitrate | 35 | 7.7 | 1.00 |
| | 0.4 wt % of | | | |
| | tetraethylammonium nitrate | | | |
| | 20 wt % of anhydrous | | | |
| | phosphoric acid | | | |
| | 007 wt % of EDTA | | | |
| | residual acetic acid | | | |
| Embodiment 2 | 0.4 wt % of ammonium nitrate | 35 | 6.3 | 1.03 |
| | 0.8 wt % of | | | |
| | tetraethylammonium nitrate | | | |
| | 20 wt % of anhydrous | | | |
| | phosphoric acid | | | |
| | 0.07 wt % of EDTA | | | |
| | residual acetic acid | | | |
| Embodiment 3 | 0.6 wt % of ammonium nitrate | 35 | 4.9 | 1.02 |
| | 0.4 wt % of | | | |
| | tetraethylammonium nitrate | | | |
| | 20 wt % of anhydrous | | | |
| | phosphoric acid | | | |
| | 0.07 wt % of EDTA | | | |
| | residual acetic acid | | | |
| Embodiment 4 | 0.6 wt % of ammonium nitrate | 35 | 6.5 | 1.05 |
| | 0.8 wt % of | | | |
| | tetraethylammonium nitrate | | | |
| | 20 wt % of anhydrous | | | |
| | phosphoric acid | | | |
| | 0.07 wt % of EDTA | | | |
| | residual acetic acid | | | |
| Embodiment 5 | 0.6 wt % of ammonium nitrate | 35 | 5.6 | 1.05 |
| | 1.0 wt % of | | | |
| | tetraethylammonium nitrate | | | |
| | 20 wt % of anhydrous | | | |
| | phosphoric acid | | | |
| | 0.07 wt % of EDTA | | | |
| | residual acetic acid | | | |
| Embodiment 6 | 0.1 wt % of ammonium nitrate | 35 | 10.0 | 0.98 |
| | 0.2 wt % of | | | |
| | tetraethylammonium nitrate | | | |
| | 20 wt % of anhydrous | | | |
| | phosphoric acid | | | |
| | 0.07 wt % of EDTA | | | |
| | residual acetic acid | | | |

TABLE 2

| | Composition of etchant | Temperature | Etch rate | Selectivity |
|---|---|---|---|---|
| | composition (wt %) | (° C.) | (Å/min) | (Top/Bottom) |
| Comparative | 0.4 wt % of ammonium nitrate | 35 | 8.7 | 1.10 |
| example 1 | 20 wt % of anhydrous | | | |
| | phosphoric acid | | | |
| | residual acetic acid | | | |
| Comparative | 0.6 wt % of ammonium nitrate | 35 | 3.6 | 1.20 |
| example 2 | 0.5 wt % of ammonium | | | |
| | phosphate | | | |
| | 0.4 wt % of | | | |
| | tetraethylammonium nitrate | | | |
| | 20 wt % of anhydrous | | | |
| | phosphoric acid | | | |
| | 0.07 wt % of EDTA | | | |
| | residual acetic acid | | | |
| Comparative | 0.6 wt % of ammonium nitrate | 35 | 3.1 | 1.90 |
| example 3 | 1.0 wt % of ammonium | | | |
| | phosphate | | | |
| | 0.4 wt % of | | | |
| | tetraethylammonium nitrate | | | |
| | 20 wt % of anhydrous | | | |
| | phosphoric acid | | | |
| | 0.07 wt % of EDTA | | | |
| | residual acetic acid | | | |
| Comparative | 0.2 wt % of ammonium nitrate | 35 | Partial | Partial |
| example 4 | 0.4 wt % of | | etching | etching |
| | tetraethylammonium nitrate | | | |
| | 10 wt % of anhydrous | | | |
| | phosphoric acid | | | |
| | 0.07 wt % of EDTA | | | |
| | residual acetic acid | | | |
| Comparative | 0.2 wt % of ammonium nitrate | 35 | 4.4 | 1.27 |
| example 5 | 0.4 wt % of | | | |
| | tetraethylammonium nitrate | | | |
| | 15 wt % of anhydrous | | | |
| | phosphoric acid | | | |
| | 0.07 wt % of EDTA | | | |
| | residual acetic acid | | | |
| Comparative | 0.4 wt % of ammonium nitrate | 35 | Partial | Partial |
| example 6 | 10 wt % of anhydrous | | etching | etching |
| | phosphoric acid | | | |
| | 0.07 wt % of EDTA | | | |
| | residual acetic acid | | | |
| Comparative | 0.4 wt % of ammonium nitrate | 35 | Partial | Partial |
| example 7 | 15 wt % of anhydrous | | etching | etching |
| | phosphoric acid | | | |
| | 0.07 wt % of EDTA | | | |
| | residual acetic acid | | | |
| Comparative | 0.6 wt % of ammonium nitrate | 35 | Partial | Partial |
| example 8 | 10 wt % of anhydrous | | etching | etching |
| | phosphoric acid | | | |
| | 0.07 wt % of EDTA | | | |
| | residual acetic acid | | | |
| Comparative | 0.6 wt % of ammonium nitrate | 35 | Partial | Partial |
| example 9 | 10 wt % of anhydrous | | etching | etching |
| | phosphoric acid | | | |
| | 0.07 wt % of EDTA | | | |
| | residual acetic acid | | | |
| Comparative | 0.8 wt % of ammonium nitrate | 35 | Partial | Partial |
| example 10 | 10 wt % of anhydrous | | etching | etching |
| | phosphoric acid | | | |
| | 0.07 wt % of EDTA | | | |
| | residual acetic acid | | | |
| Comparative | 0.8 wt % of ammonium nitrate | 35 | Partial | Partial |
| example 11 | 15 wt % of anhydrous | | etching | etching |
| | phosphoric acid | | | |
| | 0.07 wt % of EDTA | | | |
| | residual acetic acid | | | |
| Comparative | 1.0 wt % of ammonium nitrate | 35 | 6.2 | 1.36 |
| example 12 | 2.0 wt % of nitric acid | | | |
| | 20 wt % of anhydrous | | | |
| | phosphoric acid | | | |
| | 0.07 wt % of EDTA | | | |
| | residual acetic acid | | | |
| Comparative | 0.2 wt % of ammonium nitrate | 35 | Partial | Partial |
| example 13 | 20 wt % of anhydrous | | etching | etching |
| | phosphoric acid | | | |
| | CyDTA 007 wt % | | | |
| | residual acetic acid | | | |
| Comparative | 0.8 wt % of ammonium nitrate | 35 | Partial | Partial |
| example 14 | 20 wt % of anhydrous | | etching | etching |
| | phosphoric acid | | | |
| | 0.07 wt % of EDTA | | | |
| | residual acetic acid | | | |
| Comparative | 1.0 wt % of | 35 | 6.3 | 1.60 |
| example 15 | tetraethylammonium | | | |
| | nitrate | | | |
| | 20 wt % of anhydrous | | | |
| | phosphoric acid | | | |
| | 0.07 wt % of EDTA | | | |
| | residual acetic acid | | | |
| Comparative | 1.0 wt % of | 35 | Total | Total |
| example 16 | tetraethylammonium | | etching | etching |
| | nitrate | | | |
| | 20 wt % of anhydrous | | | |
| | phosphoric acid | | | |
| | 0.07 wt % of EDTA | | | |
| | residual acetic acid | | | |

First, referring to table 1, when the plurality of word lines of the integrated circuit device are formed using the etchant composition according to an embodiment of the present disclosure, the etch rate is a value in the range from 4.9 Å/min to 10.0 Å/min, which is determined as being appropriate. As the selectivity was in the range from 0.98 to 1.05, the difference in etch rate between the bottom portion and the top portion at the entrance was controlled to be at most 5%.

Referring to table 2, according to some comparison examples, as etching is not sufficiently performed, the recess recessed in the horizontal direction from the word line cut region is not formed, so the word lines are not sufficiently separated, thereby causing a failure. In addition, even if the recess is formed, as the selectivity was in the range from 1.10 to 1.90, the difference in etch rate between the bottom portion and the top portion at the entrance was shown in the range from 10% to 90%.

### Experimental Example 2

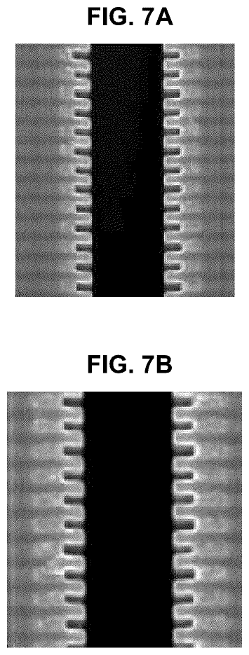

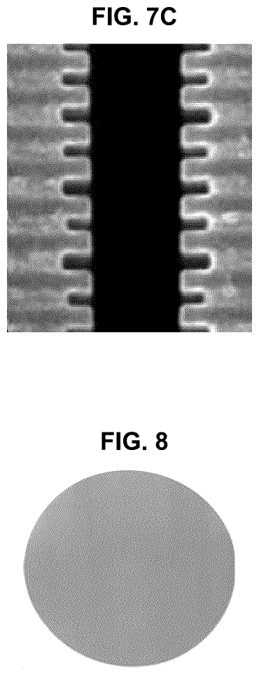

According to an embodiment of the present disclosure, the molybdenum layer of the word line cut region was partially etched using the etchant composition. FIGS. 7A to 7C are photographs obtained by capturing the word line cut region after partially etching the molybdenum layer. FIG. 7A illustrates the top portion at the entrance, which is farthest away from the substrate, of the word line cut region, FIG. 7B illustrates the intermediate portion, and FIG. 7C illustrates the bottom portion.

As recognized in FIGS. 7A to 7C, the molybdenum layer of the word line cut region was fully etched, and the recess recessed in the horizontal direction from the word line cut region was sufficiently formed. Accordingly, the word lines stacked on each other in the vertical direction were sufficiently spaced apart from each other.

### Experimental Example 3

To determine the difference between the etchant composition according to the related art and the etchant composition according to an embodiment of the present disclosure, the molybdenum layer was formed on the silicon wafer, and etching was performed with respect to the molybdenum using an oxidizing agent including acid and an oxidizing agent including salt while other conditions are maintained without change.

FIG. 8 is an etching result for the molybdenum layer using etchant compositions including oxidizing agents including an organic acid salt/an inorganic acid salt.

Referring to FIG. 8, it was recognized that the molybdenum layer was uniformly etched when the etchant composition containing salt was used.

### Experimental Example 4

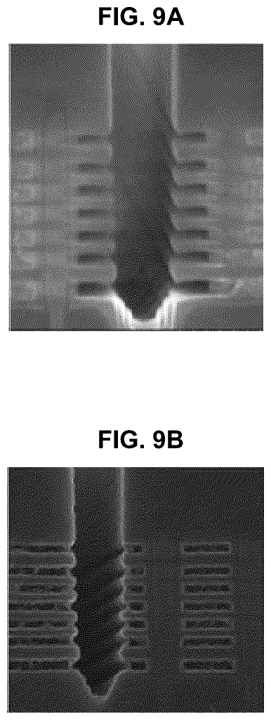

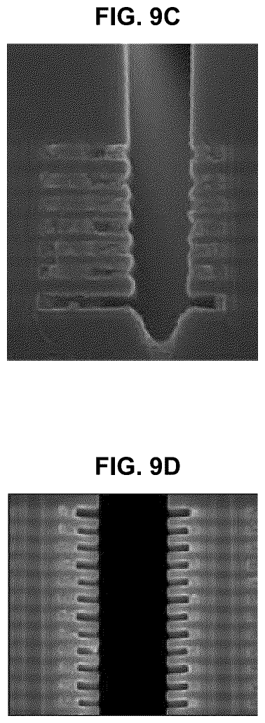

FIGS. 9A to FIG. 9D are photographs obtained by capturing etching results of etchant compositions according to the related art and the etchant composition according to the present disclosure, when the plurality of word lines are formed by removing a portion of the molybdenum layer using an etchant composition, in the method for fabricating the integrated circuit device. FIG. 9A illustrates an etching result using the etchant composition including nitric acid serving as an oxidizing agent, FIG. 9B illustrates an etching result using hydrogen peroxide, FIG. 9C illustrates an etching result hydrogen peroxide and an ammonium salt, and FIG. 9D illustrates an etching result using the etchant composition according to an embodiment of the present disclosure.

Referring to FIGS. 9A to 9C, when the etching was performed using the etchant compositions according to the related art, the etch rate was not controlled to fully etch the molybdenum layer as illustrated in FIG. 9A, or the etch rate was not controlled to fully etch the molybdenum layer and produce residues as illustrated in FIG. 9B. Alternatively, the etch rate was controlled to form the recess, but residues are produced as illustrated in FIG. 9C. However, referring to FIG. 9D, when the etching was performed using the etchant composition according to an embodiment of the present disclosure, the etch rate was controlled with respect to the whole region of the molybdenum layer to form the recess, and even the residues are never produced.

As described above, according to an embodiment of the present disclosure, when the molybdenum layer is etched using the etchant composition in the present disclosure, the etch rate may be easily controlled to easily form the desired molybdenum pattern, and the residues produced in the etching process may be limited and/or minimized. In addition, the etchant composition according to the present disclosure is employed to etch the molybdenum layer in the fabricating process for the integrated circuit device, thereby fabricating the integrated circuit device having higher quality.

Although an embodiment of the present disclosure has been described for illustrative purposes, those skilled in the art will appreciate that various modifications, and substitutions are possible, without departing from the scope and spirit of the present disclosure as disclosed in the accompanying claims.

Accordingly, the technical scope of inventive concepts is not limited to the detailed description of this specification, but should be defined by the claims.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. An etchant composition for a molybdenum layer, the etchant composition comprising:
an oxidizing agent selected from a nitrate-containing oxidizing agent, a phosphate-containing oxidizing agent, a sulfate-containing oxidizing agent, an acetate-containing oxidizing agent, or a combination thereof, the oxidizing agent including at least two types of compounds having different oxidizing powers over molybdenum,
and the at least two types of compounds being in a range from 0.1 wt % to 10 wt %, based on a total amount of the etchant composition;
a chelating agent in a range from 0.001 wt % to 10 wt %, based on the total amount of the etchant composition;
a phosphoric acid compound in a range from 15 wt % to 25 wt %, based on the total amount of the etchant composition; and
an organic solvent corresponding to a remaining portion of the etchant composition.

2. The etchant composition of claim 1, wherein
the oxidizing agent is the nitrate-containing oxidizing agent and the at least two types of compounds include a first oxidizing agent and a second oxidizing agent,
the first oxidizing agent includes metal nitrate, ammonium nitrate, or both metal nitrate and ammonium nitrate, and
the second oxidizing agent includes an alkyl ammonium nitrate containing at least one alkyl group having 1 to 6 carbon atoms.

3. The etchant composition of claim 2, wherein
the first oxidizing agent is a nitrate of alkali metal, a nitrate of alkaline earth metal, or a nitrate of transition metal.

4. The etchant composition of claim 3, wherein the first oxidizing agent is at least one of lithium nitrate (LiNO₃), sodium nitrate (NaNO₃), potassium nitrate (KNO₃), aluminum nitrate (Al(NO₃)₃), magnesium nitrate (Mg(NO₃)₂), copper nitrate (Cu(NO₃)₂), ammonium nitrate (NH₄NO₃), cobalt nitrate (Co(NO₃)₂), nickel nitrate (Ni(NO₃)₂), zinc nitrate (Zn(NO₃)₂), tungsten nitrate (W(NO₃)₂), or a combination thereof.

5. The etchant composition of claim 2, wherein the second oxidizing agent is tetraalkyl ammonium nitrate.

6. The etchant composition of claim 5, wherein the second oxidizing agent is at least one of tetramethylammonium nitrate ((CH₃)₄N(NO₃)), tetraethylammonium nitrate ((C₂H₅)₄N(NO₃)), tetrapropylammonium nitrate ((C₃H₇)₄N(NO₃)), tetrabutylammonium nitrate (((C₄H₉)₄)NNO₃), tetrapentylammonium nitrate ((C₅H₁₁)₄N(NO₃)), tetrahexylammonium nitrate ((C₆H₁₃)₄N(NO₃)), or a combination thereof.

7. The etchant composition of claim 1, wherein
the oxidizing agent includes one of ammonium phosphate ((NH₄)₃PO₄), ammonium sulfate ((NH₄)₂SO₄), ammonium acetate (C₂H₇NO₂), or a combination thereof.

8. The etchant composition of claim 1, wherein the chelating agent is a multidentate ligand with at least two bonding sites.

9. The etchant composition of claim 6, wherein the chelating agent is at least one of alkyl diamine having 2 to 14 carbon atoms, alkyl triamine having 3 to 14 carbon atoms, or a combination thereof.

10. The etchant composition of claim 6, wherein the chelating agent is at least one of ethylenediaminetetraacetic acid (EDTA; C₁₀H₁₆N₂O₈), nitrilotriacetic acid (C₆H₉NO₆), trans-1,2-diaminocyclohexane-N,N,N′,N′-tetraacetic acid (C₁₄H₂₂N₂O₈), diethylenetriaminepentaacetic acid (C_{14,}H₂₃N₃O₁₀), ethyleneglycol-O,O′-Bis(2-aminoethyl) N,N,N′,N′-tetraacetic acid (C₁₄H₂₄N₂O₁₀), triethylenetetramine-N,N,N′,N,N″′,N″′-hexaacetic acid; C₁₈H₃₀N₄O₁₂), N,N-Bis(2-hydroxyethyl) glycine (C₆H₁₃NO₄), iminoacetic acid (C₄H₇NO₄), nitrilotrimethylphosphonic acid (N(CH₂PO₃H₂)₃), or a combination thereof.

11. The etchant composition of claim 1, wherein the phosphoric acid compound is at least one of phosphoric acid, phosphate, phosphonic acid, phosphonic acid salt, or a combination thereof.

12. The etchant composition of claim 1, wherein
the organic solvent includes a non-aqueous organic solvent selected from a carboxylic acid having 1 to 7 carbon atoms, a carboxylic acid compound having 1 to 7 carbon atoms, an alcohol compound having 1 to 7 carbon atoms, a carbonic ester compound having 1 to 7 carbon atoms, and a combination thereof.

13. The etchant composition of claim 1, wherein the organic solvent includes at least one of formic acid (CH₂O₂), acetic acid (C₂H₄O₂), acrylic acid (C₃H₄O₂), propionic acid (C₃H₆O₂), butyric acid (C₄H₈O₂), valeric acid (C₅H₁₀O₂), hexanoic acid (C₆H₁₂O₂), heptanoic acid (C₇H₁₄O₂), lactic acid (C₃H₆O₃), propylene carbonate (C₄H₆O₃), dimethyl carbonate (C₃H₆O₃), or a combination thereof.

14. The etchant composition of claim 1, wherein the organic solvent is 75 wt % to 85 wt % of the etchant composition, based on the total amount of the etchant composition.

15. A method for patterning a molybdenum layer, the method comprising:
forming the molybdenum layer on a substrate;
forming an etch stop layer on the molybdenum layer; and
etching the molybdenum layer using the etchant composition of claim 1 and employing the etch stop layer as a mask.

16. The method of claim 15, wherein
the oxidizing agent is the nitrate-containing oxidizing agent and the at least two types of compounds include a first oxidizing agent and a second oxidizing agent, the first oxidizing includes metal nitrate, ammonium nitrate, or both metal nitrate and ammonium nitrate, and
the second oxidizing agent includes an alkyl ammonium nitrate containing at least one alkyl group having 1 to 6 carbon atoms.

17. A method for forming a molybdenum pattern, the method comprising:
forming a support structure on a substrate, the support structure extending in a horizontal direction and defining a plurality of spaces spaced apart from each other in a vertical direction;
forming a molybdenum layer by filling molybdenum in the plurality of spaces; and
removing a portion of the molybdenum layer in a vertical direction perpendicular to a top surface of the substrate using an etchant composition for the molybdenum layer, such that molybdenum patterns filling the plurality of spaces are formed, the molybdenum patterns being spaced apart from each other in the vertical direction, wherein
the etchant composition for the molybdenum layer includes
an oxidizing agent selected from a nitrate-containing oxidizing agent, a phosphate-containing oxidizing agent, a sulfate-containing oxidizing agent, an acetate-containing oxidizing agent, or a combination thereof, the oxidizing agent including at least two types of compounds having different oxidizing powers over molybdenum, and the at least two types of compounds being in a range from 0.1 wt % to 10 wt %, based on a total amount of the etchant composition,
a chelating agent in a range from 0.001 wt % to 10 wt %, based on the total amount of the etchant composition,
a phosphoric acid compound in a range from 15 wt % to 25 wt %, based on the total amount of the etchant composition, and
an organic solvent corresponding to a remaining portion of the etchant composition.

18. The method of claim 17, wherein
the oxidizing agent is the nitrate-containing oxidizing agent and the at least two types of compounds include a first oxidizing agent and a second oxidizing agent,
the first oxidizing agent includes metal nitrate, ammonium nitrate, or both metal nitrate and ammonium nitrate, and
the second oxidizing agent includes an alkyl ammonium nitrate containing at least one alkyl group having 1 to 6 carbon atoms.

19. A method for fabricating an integrated circuit device including a plurality of word lines, a plurality of bit lines, and channel structures connected to the word lines and the bit lines, the method comprising:
forming a stack structure by alternately stacking a plurality of first layers and a plurality of second layers on a substrate;
forming a channel hole through the stack structure in a vertical direction;
forming the channel structure in the channel hole;
forming a word line cut region through the stack structure in the vertical direction, the word line cut region extending in a first direction parallel to a top surface of the substrate, the word line cut region exposing the plurality of first layers;
forming a plurality of word line spaces by removing the plurality of first layers;
forming a molybdenum layer by filling the plurality of word line spaces, the molybdenum layer covering a surface of plurality of second layers exposed through the word line cut region;
removing a portion of the molybdenum layer using an etchant composition, thereby forming a plurality of word lines including a plurality of molybdenum patterns, the plurality of word line filling the plurality of word line spaces and being spaced apart from each other in the vertical direction; and
forming bit lines on the stack structure, wherein
the etchant composition for the molybdenum layer includes
an oxidizing agent selected from a nitrate-containing oxidizing agent, a phosphate-containing oxidizing agent, a sulfate-containing oxidizing agent, an acetate-containing oxidizing agent, or a combination thereof, the oxidizing agent including at least two types of compounds having different oxidizing powers over molybdenum, and the at least two types of compounds being in a range from 0.1 wt % to 10 wt %, based on a total amount of the etchant composition,
a chelating agent in a range from 0.001 wt % to 10 wt %, based on the total amount of the etchant composition,
a phosphoric acid compound in a range from 15 wt % to 25 wt %, based on the total amount of the etchant composition, and
an organic solvent corresponding to a remaining portion of the etchant composition.

20. The method of claim 19, wherein
the oxidizing agent is the nitrate-containing oxidizing agent and the at least two types of compounds include a first oxidizing agent and a second oxidizing agent,
the first oxidizing agent includes metal nitrate, ammonium nitrate, or both metal nitrate and ammonium nitrate, and
the second oxidizing agent includes an alkyl ammonium nitrate containing at least one alkyl group having 1 to 6 carbon atoms.
